(19) United States
(12) Patent Application Publication
(10) Pub. No.: US 2026/0040462 A1
(43) Pub. Date: Feb. 5, 2026

(54) MULTILAYER DEFORMABLE LIQUID-METAL CIRCUITS AND INTERCONNECTS WITH IMPROVED RELIABILITY

(71) Applicant: Meta Platforms Technologies, LLC, Menlo Park, CA (US)

(72) Inventors: Omar Awartani, Redmond, WA (US); Adam Swett, Seattle, WA (US); Marcos Antonio Santana Andrade, JR., Seattle, WA (US); John Uehlin, Redmond, WA (US); Yunsik Ohm, Redmond, WA (US); Michael Tawfik Khbeis, Federal Way, WA (US); Behnam Sadri, Redmond, WA (US); Shiv Kumar Agarwal, Bellevue, WA (US); Benjamin Cook, Woodinville, WA (US); Nazila Dadvand, Redmond, WA (US); James Andrew Hammer, Kirkland, WA (US)

(21) Appl. No.: 19/288,925

(22) Filed: Aug. 1, 2025

Related U.S. Application Data
(60) Provisional application No. 63/679,057, filed on Aug. 2, 2024.
(60) Provisional application No. 63/679,037, filed on Aug. 2, 2024.

(51) Int. Cl. H05K 3/32; H05K 1/02; H05K 1/09; H05K 1/11; H05K 1/18; H05K 3/30

(52) U.S. Cl. CPC H05K 3/32; H05K 1/028; H05K 1/0283; H05K 1/09; H05K 1/115; H05K 1/181; H05K 1/189; H05K 3/303; H05K 2201/09609; H05K 2201/09618

(57) ABSTRACT

A method of the subject technology includes obtaining a first electronic component comprising a first plurality of contacts and/or pins, obtaining an electronic part comprising a first plurality of circuit components corresponding to the first plurality of contacts and/or pins and forming a first layer over the first plurality of circuit components. The method further includes forming a first plurality of liquid metal (LM) interconnects in the first layer at locations corresponding to the first plurality of circuit components.

### CROSS REFERENCE TO RELATED APPLICATIONS

The present disclosure is related and claims priority under 35 USC § 119 (e) to U.S. Provisional Application No. 63/679,037, entitled “MULTILAYER DEFORMABLE LIQUID-METAL CIRCUITS AND SYSTEMS, METHODS, AND DEVICES THEREFORE,” filed on Aug. 2, 2024 and U.S. Provisional Application No. 63/679,057, entitled LIQUID METAL INTERCONNECTS FOR IMPROVED RELIABILITY IN FLEXIBLE AND STRETCHABLE CIRCUITS,” filed on Aug. 2, 2024, the contents of which are herein incorporated by reference, in their entirety, for all purposes.

### TECHNICAL FIELD

The present disclosure generally relates to liquid metal (LM) circuits, and more particularly, to multilayer deformable liquid-metal circuits and interconnect with improved reliability.

### BACKGROUND

Flexible circuits have become a desirable product due to their ability for application with a wide variety of use capabilities for prolonged durations of time. However, conventional solutions are insufficient for use with flexible and stretchable electronics. For instance, conventional fabrication methods are time-consuming, and conventional flexible electronics are relatively thick and stiff. Further, conventional solutions do not provide reliable and elastically deformable interconnections to connect prefabricated microelectronic parts.

### SUMMARY

According to some aspects, a method of the subject technology includes obtaining a first electronic circuit (e.g., an integrated circuit) comprising a first plurality of contacts and/or pins, obtaining an electronic part comprising a first plurality of circuit components corresponding to the first plurality of contacts and/or pins and forming a first layer over the first plurality of circuit components. The method further includes forming a first plurality of LM interconnects in the first layer at locations corresponding to the first plurality of circuit components.

According to other aspects, a device of the subject technology includes obtaining a substrate comprising, a first plurality of channels and a second plurality of channels. The method further includes forming a plurality of ports, and filling the first plurality of channels and the second plurality of channels, through at least a subset of the plurality of ports, with an LM, thereby producing a plurality of deformable LM components.

According to yet other aspects, an electronic device of the subject technology includes a first electronic component comprising a first plurality of contacts and/or pins and a second electronic component comprising a second plurality of contacts and/or pins, an electronic part comprising a first plurality of circuit components corresponding to the first plurality of contacts and/or pins and a second plurality of circuit components corresponding to the second plurality of contacts and/or pins of the second electronic component. The electronic device further includes a first layer over the first plurality of circuit components and a second layer over the second plurality of circuit components.

### BRIEF DESCRIPTION OF THE DRAWINGS

To easily identify the discussion of any particular element or act, the most significant digit or digits in a reference number refer to the figure number in which that element is first introduced.

FIG. 1 is a block diagram schematically illustrating an example of a distributed additive manufacture system topology including a computer system and an additive manufacture system, in accordance with some embodiments of the present disclosure.

FIG. 2 is a block diagram illustrating various modules and/or components of a computer system, in accordance with some embodiments of the present disclosure.

FIG. 3 is a schematic diagram illustrating a cross-sectional view of an exemplary deformable electronic device, in accordance with some embodiments of the present disclosure.

FIGS. 4A, 4B and 4C are flow diagrams collectively illustrating an exemplary method for forming deformable electrical devices, in accordance with some embodiments of the present disclosure.

FIG. 5 is a process flow diagram illustrating an example of a method for forming deformable electrical devices, in accordance with some embodiments of the present disclosure.

FIGS. 6A and 6B are top and cross-sectional views illustrating an example of a stack of vias, in accordance with some embodiments of the present disclosure.

FIG. 7 is a schematic diagram illustrating various vias, in accordance with some embodiments of the present disclosure.

FIG. 8 is a schematic diagram illustrating Xray height and width measurements of various vias, in accordance with some embodiments of the present disclosure.

FIGS. 9A and 9B are schematic diagrams illustrating examples of designs of contacts and/or pins for an integrated circuit (IC), in accordance with some embodiments of the present disclosure.

FIG. 10 is a schematic diagram illustrating an example of a deformable electronic device, in accordance with some embodiments of the present disclosure.

FIGS. 11A, 11B, 11C, 11D, and 11E are schematic cross-sectional views of example structures of the deformable electronic device of FIG. 10, in accordance with some exemplary embodiments of the present disclosure.

FIGS. 12A, 12B, and 12C are flowcharts collectively illustrating a method for manufacturing an electronic device, in accordance with some embodiments of the present disclosure.

FIG. 13A is a schematic diagram illustrating an example of an initial substrate, in accordance with some exemplary embodiments of the present disclosure.

FIG. 13B is a process flow diagram illustrating an example of a method for forming deformable electrical devices, in accordance with some embodiments of the present disclosure.

FIG. 14 is a process flow diagram illustrating an example of a method for forming deformable electrical devices, in accordance with some embodiments of the present disclosure.

FIG. 15 is a schematic diagram illustrating an example of an initial substrate, in accordance with some exemplary embodiments of the present disclosure.

FIG. 16 is a schematic diagram illustrating an example of a deformable electrical device, in accordance with some embodiments of the present disclosure.

FIG. 17 is a schematic diagram illustrating an example of a deformable electrical device, in accordance with some embodiments of the present disclosure.

FIG. 18 is a schematic diagram illustrating an example of an implementation of the deformable electronic device in the form of a glove, in accordance with some embodiments of the present disclosure.

In one or more implementations, not all of the depicted components in each figure may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### DETAILED DESCRIPTION

The detailed description set forth below describes various configurations of the subject technology and is not intended to represent the only configurations in which the subject technology may be practiced. The detailed description includes specific details for the purpose of providing a thorough understanding of the subject technology. Accordingly, dimensions may be provided in regard to certain aspects as non-limiting examples. However, it will be apparent to those skilled in the art that the subject technology may be practiced without these specific details. In some instances, well-known structures and components are shown in block diagram form in order to avoid obscuring the concepts of the subject technology.

It is to be understood that the present disclosure includes examples of the subject technology and does not limit the scope of the included clauses. Various aspects of the subject technology will now be disclosed according to particular but non-limiting examples. Various embodiments described in the present disclosure may be carried out in different ways and variations, and in accordance with a desired application or implementation.

In the following detailed description, numerous specific details are set forth to provide a full understanding of the present disclosure. It will be apparent, however, to one ordinarily skilled in the art, that embodiments of the present disclosure may be practiced without some of the specific details. In other instances, well-known structures and techniques have not been shown in detail so as not to obscure the disclosure.

Some aspects of the subject disclosure are directed to providing systems, methods, and devices for producing deformable electronic devices having deformable interconnects that can maintain electrical communications when the deformable electronic devices are subjected to one or more certain conditions (e.g., strain, cycle, temperature, bending, etc.) and/or physically deformed. In particular, the present disclosure provides LM interconnects and methods thereof for improved reliability in flexible and stretchable circuits.

In various embodiments, the present disclosure provides a deformable electronic device. The deformable device includes: a first IC; an electronic part; and a first plurality of deformable interconnects formed of an LM material and electrically connecting the first IC with the electronic part. In some embodiments, the first IC includes a first plurality of contacts and/or pins. The electronic part includes a first plurality of circuit components corresponding to the first plurality of contacts and/or pins of the first IC. The first plurality of deformable interconnects is formed by any method disclosed herein. In some embodiments, the first IC is a chip. In some embodiments, the electronic part includes a flexible and/or stretchable electronic interposer.

In some embodiments, the deformable electronic device further includes: a second IC, and a second plurality of deformable interconnects formed of the LM material and electrically connecting the second IC with the electronic part.

In other aspects, the present disclosure provides deformable electronic devices with multi-layer flexible and stretchable LM circuits, and novel methods for fabricating such deformable electronic devices. The novel methods of the present disclosure enable leveraging of flexible printed circuit (FPC) vendor fabrication capabilities and can make deformable electronic devices with reduced bending stiffness and enhanced trace density. The methods of the present disclosure can also reduce the patterning time of deformable components (e.g., multi-layer flexible and stretchable LM circuits) and enable rapid manufacture of deformable electronic devices.

In some aspects, the deformable electronic device of the subject technology includes a substrate having a thickness of about 350 microns or less. The substrate includes: a first dielectric (e.g., polyimide) layer having a thickness of between 15 microns and 60 microns; a second dielectric layer having a thickness of between 15 microns and 60 microns; at least one middle dielectric layer sandwiched between the first and second dielectric layers, wherein the at least one middle dielectric layer collectively has a thickness of between 15 and 60 microns. The deformable electronic device also includes: a first plurality of deformable LM traces disposed in the first dielectric layer, a second plurality of deformable LM traces disposed in the second dielectric layer, and a plurality of deformable LM vias. Each trace in the first plurality of deformable LM traces has a depth of between 15 microns and 60 microns and a width of more than 200 microns. Each trace in the second plurality of deformable LM traces has a depth of between 15 microns and 60 microns and a width of between 15 microns and 60 microns. Each respective deformable LM via in the plurality of deformable LM vias is in electrical communication with at least one of (i) a corresponding deformable LM trace in the first plurality of LM traces and (ii) a corresponding deformable LM trace in the second plurality of LM traces across the at least one middle dielectric layer.

In some embodiments, the substrate further includes a third layer stacked on the first or second dielectric layer, and the electronic device further includes a plurality of deformable LM components. At least a portion of each deformable LM component in the plurality of deformable LM components is disposed in the third layer.

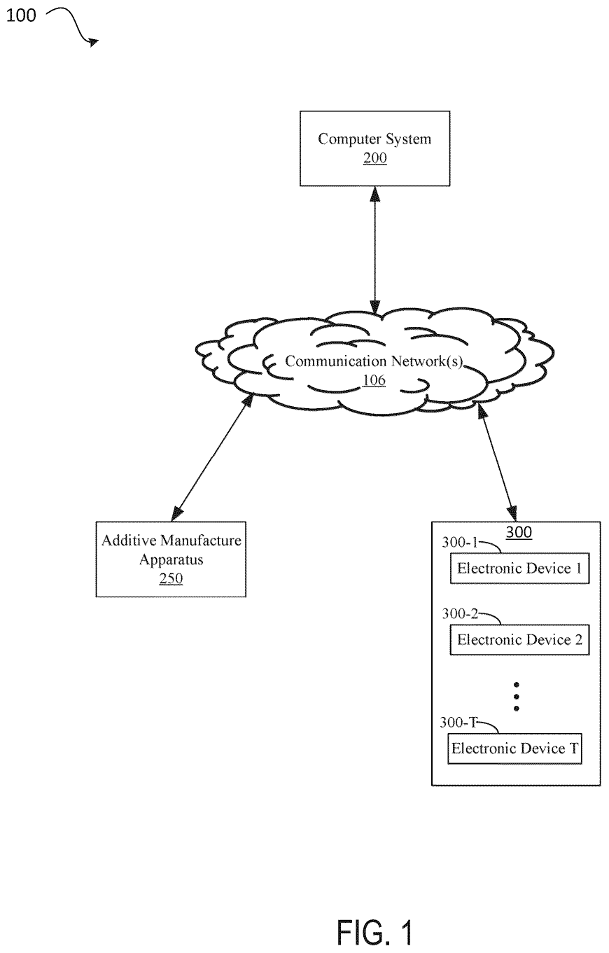

Turning now to the figures, FIG. 1 is a block diagram schematically illustrating an example of a topology of a distributed additive manufacture system 100 including a computer system and an additive manufacture system, in accordance with some embodiments of the present disclosure. In some embodiments, the distributed additive manufacture system 100 includes a computer system 200 that facilitates manufacture of an electronic device 300 in response to one or more instructions for manufacturing the electronic device 300. In some embodiments, the computer system 200 and an additive manufacture apparatus (e.g., additive manufacture apparatus 250 of FIG. 1, etc.) are in a single monolithic casing without a communication network 106. In other embodiments, the computer system 200 and the additive manufacture apparatus 250 are separated by some distance and are in electrical communication with each other over the communication network as illustrated in FIG. 1.

In some embodiments, the communication networks 106 optionally include the Internet, one or more local area networks (LANs), one or more wide area networks (WANs), other types of networks, or a combination of such networks. Examples of communication networks 106 include the World Wide Web (WWW), an intranet and/or a wireless network, such as a cellular telephone network, a wireless local area network (LAN) and/or a metropolitan area network (MAN), and other devices by wireless communication.

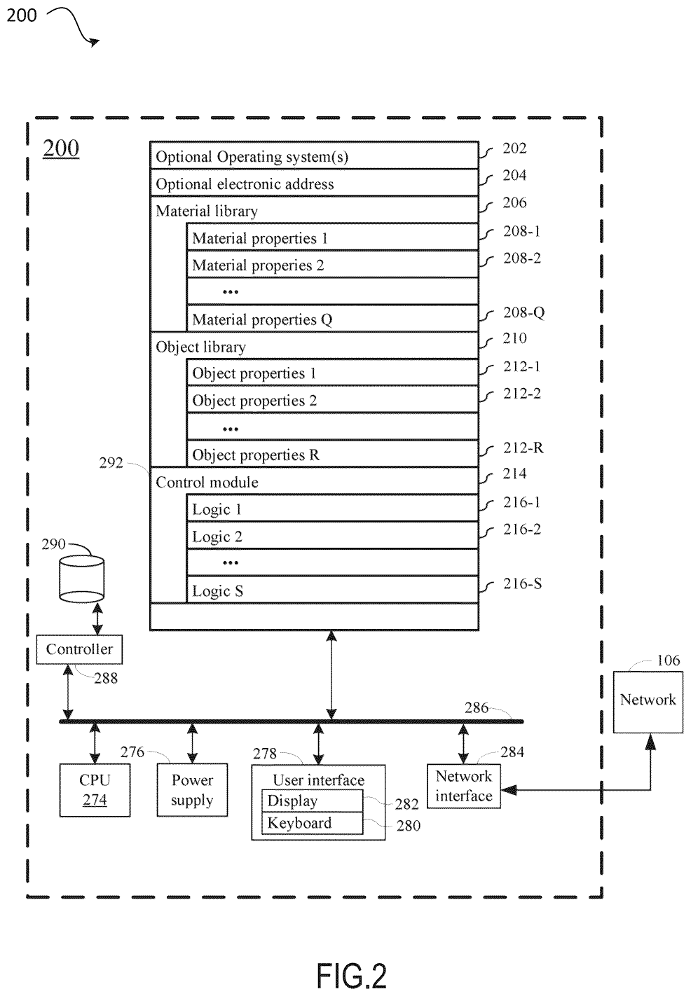

FIG. 2 is a block diagram illustrating various modules and/or components of the computer system 200 of FIG. 1, in accordance with some embodiments of the present disclosure. The computer system 200 for controlling the additive manufacture apparatus 250 of FIG. 1 by providing one or more instructions, such as one or more non-transitory logics for manufacture of an electronic device 300 will be described with reference to FIG. 2.

In various embodiments, the computer system 200 includes one or more processing units (CPUs) 274, a network or other communications interface 284, and memory 292. The memory 292 includes high-speed random-access memory, such as DRAM, SRAM, DDR RAM, or other random-access solid state memory devices, and optionally also includes non-volatile memory, such as one or more magnetic disk storage devices, optical disk storage devices, flash memory devices, or other non-volatile solid state storage devices. The memory 292 may optionally include one or more storage devices remotely located from the CPU(s) 274. The memory 292, or alternatively the non-volatile memory device(s) within memory 292, includes a non-transitory computer-readable storage medium. Access to memory 292 by other components of the computer system 200, such as the CPU(s) 274, is, optionally, controlled by a controller. In some embodiments, memory 292 can include mass storage that is remotely located with respect to the CPU(s) 274. In other words, some data stored in memory 292 may in fact be hosted on devices that are external to the computer system 200, but that can be electronically accessed by the computer system 200 over an Internet, intranet, or other form of communication network 106 or electronic cable using communication interface 284.

In some embodiments, memory 292 stores an optional operating system 202 that includes procedures for handling various basic system services; an optional electronic address 204 associated with the computer system 200 that identifies the computer system 200; a material library 206 that stores a plurality of material properties 208 associated with a corresponding material that is utilized by the additive manufacture apparatus 250; an object library 210 that stores a plurality of object properties 212 for manufacturing a corresponding object, such as a circuit (e.g., a layer of the circuit) and/or a circuit component at the additive manufacture apparatus 250; and a control module 214 that stores one or more non-transitory logics 216 that instruct a control of a manufacture of the corresponding object at the additive manufacture apparatus 250.

In some embodiments, an electronic address 204 is associated with the computer system 200. The electronic address 204 is utilized to identify the computer system 200 at least uniquely from other devices and components of the distributed additive manufacture system 100 (e.g., uniquely identify computer system 200 from additive manufacture apparatus 250 of FIG. 1).

In some embodiments, a material library 206 is configured to store at least a plurality of material properties 208 (280-1 through 208-Q) that is associated with a corresponding material (e.g., first plurality of material properties 208-1 is associated with a corresponding first material, second plurality of material properties 208-2 is associated with a corresponding second material, etc.). Each corresponding material associated with a respective plurality of material properties 208 is found at or produced by the additive manufacture apparatus 250. For instance, in some embodiments, the corresponding material associated with the plurality of material properties 208 is a resin accommodated by a resin enclosure of the additive manufacture apparatus 250. In some embodiments, the corresponding material associated with the plurality of material properties 208 is a media of the additive manufacture apparatus 250. Moreover, in some embodiments, the corresponding material associated with the plurality of material properties 208 is a material of the resin enclosure or a different component of the 3D printer system (e.g., outer glass container, temperature control system, etc.). For instance, in some embodiments, the corresponding material associated with the plurality of material properties 208 is a coolant of a thermal control system associated with an additive manufacture apparatus 250.

In some embodiments, a respective material property 208 in the plurality of material properties 208 is associated with a physical property of the corresponding material. As a nonlimiting example, in some such embodiments, the physical property of the corresponding material associated with the respective material property is a first model of a phase diagram of the corresponding material that includes an evaluation of a boiling point, a melting point, a critical point, a supercritical fluidic phase region of the corresponding material, an evaluation of a glass transition temperature, or a combination thereof. As another non-limiting example, in some embodiments, the physical property of the corresponding material associated with the respective material property 208 is a second model of a viscosity of the corresponding material, a third model of an index of refraction of the corresponding material, a fourth model of an evaluation of a depth of curing of the corresponding material volumetric shrinkage of the corresponding material, a fifth model of a flexural strength of the corresponding material, or a combination thereof. In some embodiments, the physical property of the corresponding material is a thermal property, such as a sixth model of a thermal conductivity of the corresponding material, a seventh model of a thermal diffusivity of the corresponding material, an eight model of a specific heat capacity, a ninth model of a thermal effusivity of the corresponding model, a tenth model of a material density of the corresponding material, an eleventh model of a conductivity of the corresponding material, or a combination thereof.

In some embodiments, from the plurality of material properties 208 associated with the physical property of the corresponding material, a manufacture of an object, such as an interconnect of the present disclosure, is dynamically modifiable based on one or more material properties in the plurality of material properties 208, such as by changing a mass of the material deposited by an additive manufacture apparatus 250 when manufacturing the object.

For instance, in some embodiments, the respective material property in the plurality of material properties 208 is associated with the supply of the corresponding material at an additive manufacture apparatus 250, such as the amount (e.g., a weight, a volume, etc.) of a reservoir of the corresponding material at the additive manufacture apparatus 250. One skilled in the art of the present disclosure will appreciate that a wide domain of material properties 208 are applicable to the systems, methods, and devices of the present disclosure. In some embodiments, the plurality of material properties 208 stored by the material library 206 includes between 5 material properties and 10,000 material properties.

In some embodiments, the object library 210 is configured to store at least a plurality of object properties 212 (212-1 to 212-R) that is associated with a corresponding object (e.g., first plurality of object properties 212-1 is associated with a corresponding first object, second plurality of material properties 212-2 is associated with a corresponding second object, etc.). In some embodiments, a respective object property 212 in the plurality of object properties 212 includes a set of non-transitory instructions for manufacturing the corresponding object at an additive manufacture apparatus 250 by way of one or more additive manufacturing techniques. For instance, in some embodiments, the first object property in a first plurality of object properties 212-1 includes a first set of non-transitory instructions for manufacturing a corresponding second object at a direct writing additive manufacture apparatus 250, the second object property in the first plurality of object properties 212-1 includes a second set of non-transitory instructions for manufacturing the corresponding second object at a screen printing additive manufacture apparatus 250, and the like. In some embodiments, the plurality of object properties 212 stored by the object library 210 includes between 5 object properties and 10,000 object properties.

In some embodiments, the control module 214 stores one or more non-transitory logics 216 (e.g., first non-transitory logic 216-1, second non-transitory logic 216-2, . . . , non-transitory logic 216-S). In some embodiments, each of the non-transitory logics 216 is configured to control an aspect of an additive manufacture apparatus 250 by one or more instructions for the additive manufacture apparatus 250. For instance, in some embodiments, a respective non-transitory logic 216 includes one or more instructions to modify a flow rate of a material disposed (e.g., extruded) by the additive manufacture apparatus 250, and the like. As another non-limiting example, in some embodiments, a respective non-transitory logic 216 is configured to switch the power state of the system 100 (e.g., a 3D printer), such as the respective powered state (e.g., switch to/from a powered state, an unpowered stated, etc.) of a power supply of the additive manufacture apparatus 250, the respective powered state of a temperature control system of the additive manufacture apparatus 250, or a combination thereof.

In some embodiments, the object library 210 is subsumed by, or in communication with, the control module 214. For instance, in some embodiments, the non-transitory logic 216 of the control module 214 includes a geometric slicer for translating slicing a corresponding object for manufacture at an additive manufacture apparatus 250.

Each of the above identified modules and applications correspond to a set of executable instructions for performing one or more functions described above and the methods described in the present disclosure. These modules (e.g., sets of instructions) need not be implemented as separate software programs, procedures or modules, and thus various subsets of these modules are, optionally, combined or otherwise re-arranged in various embodiments of the present disclosure. In some embodiments, memory 292 optionally stores a subset of the modules and data structures identified above. Furthermore, in some embodiments, the memory 292 stores additional modules and data structures not described above.

It should be appreciated that the computer system 200 of FIG. 2 is only one example of a computer system 200, and that the computer system 200 optionally has more or fewer components than shown, optionally combines two or more components, or optionally has a different configuration or arrangement of the components. The various components shown in FIG. 2 including the CPU 276, user interface 278, network interface 280, bus 286, controller 288 and memory 290 are implemented in hardware, software, firmware, or a combination thereof, including one or more signal processing and/or application specific ICs.

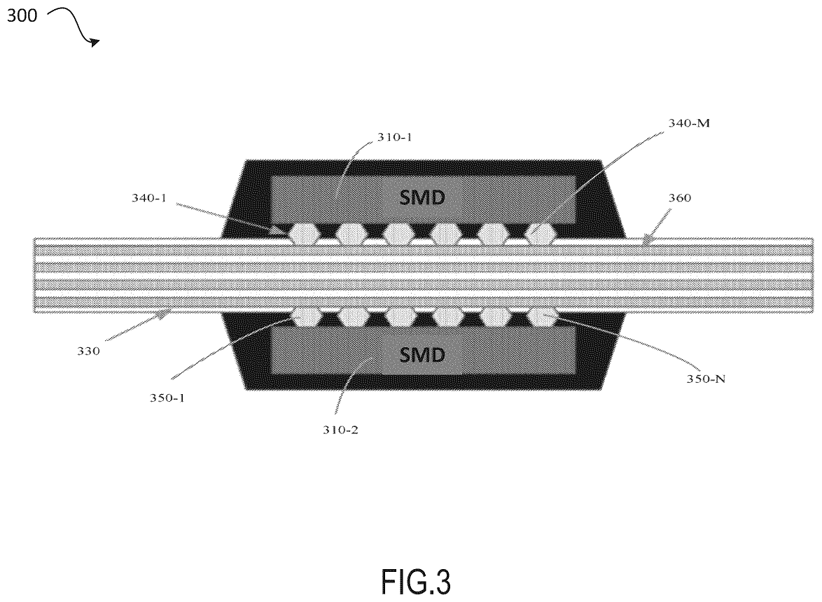

FIG. 3 is a schematic diagram illustrating a cross-sectional view of an exemplary deformable electronic device in accordance with some embodiments of the present disclosure. The electronic device 300 may include a number of electronic devices 300-1, 300-2 . . . 300-T as shown in FIG. 1. The deformable electronic device 300 generally includes one or more ICs, an electronic part, and one or more pluralities of deformable interconnects electrically connecting the one or more ICs with the electronic part. For instance, as a non-limiting example, FIG. 3 illustrates the deformable electronic device 300 including a first surface-mount device (SMD) 310-1 and an electronic part 330. The first SMD 310-1 is electrically connected to the electronic part 330 by a first plurality of deformable interconnects 340 and the second SMD 310-2 is electrically connected to the electronic part 330 by a second plurality of deformable interconnects 350.

While two SMDs are shown and are placed on each side of the electronic part, it should be noted that this is by way of example and it is non-limiting. The deformable electronic device 300 can include any suitable number of SMDs. For instance, in an exemplary embodiment, the deformable electronic device 300 consists of a single SMD. In some embodiments, the deformable electronic device 300 includes more than two, more than five, more than 10, more than 20, more than 50, or more than 100 SMDs. In some embodiments, all the ISMDs are disposed on one side of the deformable electronic device 300. Alternatively, in some embodiments, a set of SMDs is disposed on one side of the deformable electronic device 300 and another set of SMDs is disposed on another side of the deformable electronic device 300.

The first SMD 310-1 or the second SMD 310-2 can include 410, such as transistors, resistors, and capacitors, and can be configured to achieve one or more specific functions. In some embodiments, the first SMD 310-1 or the second SMD 310-2 is a chip.

In some embodiments, the electronic part 330 is deformable, i.e., being a deformable part. In some embodiments, the electronic part 330 is deformable and includes a backplane including, but not limited to, for example, flexible printed circuit (FPC). Advantageously, the backplane (e.g., FPC) can be used to connect multiple ICs and/or other electronic devices such as memory modules, input, output cards or other types of devices. It can provide power and data connections between these ICs, modules and/or devices, and allow them to communicate and exchange information. It allows easy and efficient interconnection of multiple electronic components and simplifies the assembly of complex electronic systems. It provides simplified interconnectivity and reduces the risk of signal loss. It improves overall system reliability, scalability, and signal integrity.

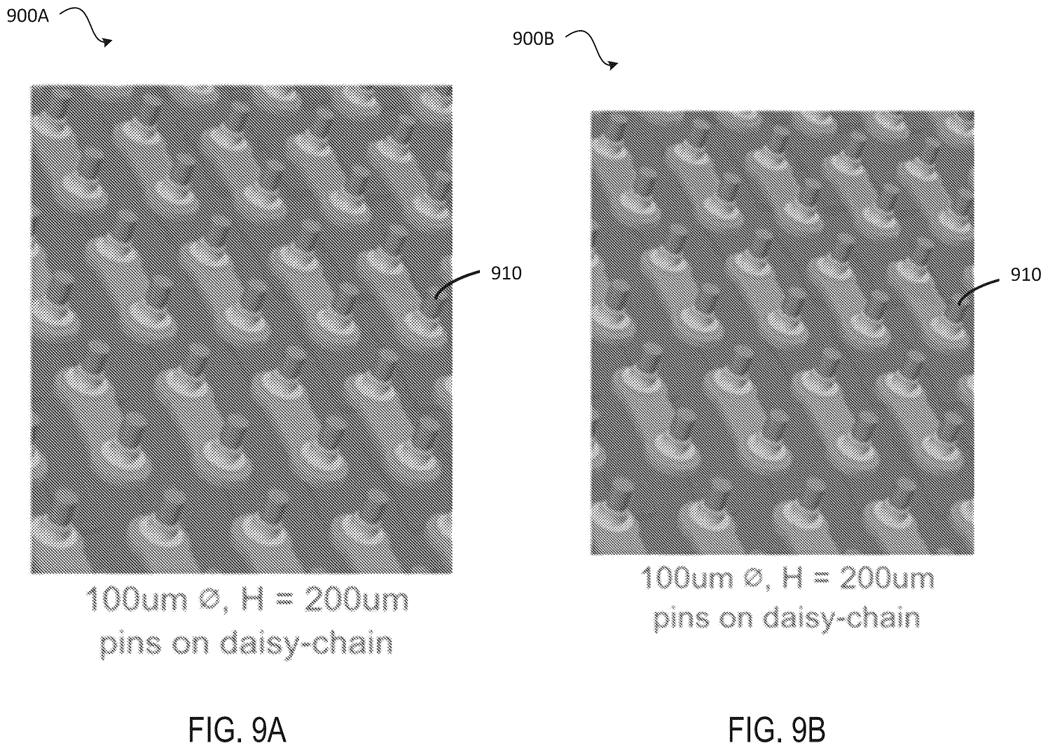

In some embodiments, the first SMD 310-1 includes a first plurality of contacts and/or pins, such as contacts and/or pins 910 illustrated in FIGS. 9A and 9B. In some embodiments, the electronic part 330 includes a first plurality of circuit components corresponding to the first plurality of contacts and/or pins of the first SMD 310-1. In some embodiments, the first plurality of deformable interconnects includes one or more contact pads, one or more traces, one or more vias, or any combinations thereof. In some embodiments, the first plurality of deformable interconnects 340 electrically connects the first plurality of contacts and/or pins of the first SMD 310-1 with the first plurality of circuit components of the electronic part 330.

Similarly, in some embodiments, the second SMD 310-2 includes a second plurality of contacts and/or pins. In some embodiments, the electronic part 330 includes a second plurality of circuit components corresponding to the second plurality of contacts and/or pins of the second SMD 310-2. In some embodiments, the second plurality of deformable interconnects includes one or more contact pads, one or more traces, one or more vias, or any combinations thereof. In some embodiments, the second plurality of deformable interconnects 350 electrically connects the second plurality of contacts and/or pins of the second SMD 310-2 with the second plurality of circuit components of the electronic part 330.

In some embodiments, the electronic part 330 is deformable, being a deformable part. As used herein, the term “deformable part” refers to a part or a portion of it (e.g., a layer) capable of altering its shape subject to pressure or stress. For instance, in some embodiments, a deformable part (e.g., the electronic part 330) or at least a portion of it is flexible, bendable, stretchable, inflatable, or the like. In some embodiments, a deformable part or at least a portion of it (e.g., a layer) is made with a material having a low Young's Modulus. Such a material allows a deformable part or a portion of it to deform (e.g., bend, stretch or the like) under pressure or strain. In some embodiments, a deformable part or at least a portion of it is made of a material to provide enhanced flexibility and tackability. Examples of materials with low Young's Modulus include, but are not limited to, elastomeric materials, viscoelastic polymeric materials, synthetic resins having low sliding performance, high corrosion resistance and high strength, such as silicone, medical grade polyurethane, polyethylene terephthalate (PET), dielectric (PI), polyphenylene sulfide (PPS) or fluorine-containing resin.

In some embodiments, a deformable part (e.g., the electronic part 330) includes a layer or a portion made of a relatively rigid material. For instance, in some embodiments, a deformable part includes a layer or a portion made of a material having Young's Modulus. Examples of materials with relatively higher Young's Modulus include, but are not limited to, polyethylene, PEEK, polyester, aramid, composite, glass epoxy, and polyethylene naphthalene.

In some embodiments, a deformable part (e.g., the electronic part 330) includes a supporting material upon or within an object is fabricated or attached to or on. In some embodiments, a deformable part or a portion of the deformable part is processed (e.g., patterned) during manufacture of the object. In some embodiments, a deformable part remains substantially unchanged when the object is formed upon or within the deformable part. In some embodiments, a deformable part includes a planar surface, a substantially planar surface, a curved surface, a round surface (e.g., an edge having a radius of curvature greater than zero), one or more sharp edges, or any combination thereof.

In some embodiments, a deformable part (e.g., the electronic part 330) is a monolayer part consisting of a single layer. In some embodiments, a deformable part (e.g., the electronic part 330) includes two, three, four, five, or more than five layers. In some embodiments, a deformable part includes one or more layers that are removable, e.g., functioning as a sacrificial layer that can be at least partially removed when desired or needed.

A deformable part (e.g., the electronic part 330) can be of any suitable shape and size. For instance, in some embodiments, a deformable part has a thickness, e.g., the electronic part 330 has a thickness in the vertical direction in FIG. 3. In some embodiments, the thickness of a deformable part is within a range of about 1 to 5 mm. In some embodiments, the thickness of at least a portion of a deformable part is within a range of about 100 μm to 1000 μm.

A surface of a deformable part (e.g., the electronic part 330) can be of any suitable shape and size. For instance, a surface of a deformable part can be a planar surface, a substantially planar surface, a curved surface, a round surface, or any combination thereof. A surface of a deformable part can have an area within a range from about 1 square millimeters (mm²) to about 100 square meters (m²) or greater.

As used herein, the term “deformable interconnect” refers to an interconnect or a portion of it capable of altering its shape subject to force, pressure, or stress. For instance, in some embodiments, a deformable interconnect (e.g., the interconnect 340-1, 340-M, 350-1, 350-N) or at least a portion of it is flexible, bendable, stretchable, or the like.

The deformable electronic device 300 can include any suitable number of deformable interconnects to connect an IC or module or other device with the electronic part 330. For instance, depending in part on the first SMD 310-1 and the electronic part 330, the first plurality of deformable interconnects 340 can include two, three, four, five, six, seven, eight, nine, ten, or more than ten deformable interconnects to connect the first SMD 310-1 with the electronic part 330. In an exemplary embodiment, the deformable electronic device 300 may include a single deformable interconnect to connect the first SMD 310-1 with the electronic part 330. Similarly, depending in part on the second SMD 310-2 and the electronic part 330, the second plurality of deformable interconnects 350 can include two, three, four, five, six, seven, eight, nine, ten, or more than ten deformable interconnects to connect the second SMD 310-2 with the electronic part 330. In an exemplary embodiment, the deformable electronic device 300 may include a single deformable interconnect to connect the second SMD 310-2 with the electronic part 330.

In some embodiments, a deformable interconnect (e.g., the interconnect 340-1, 340-M, 350-1, 350-N) is made of a liquid metal material. As used herein, the term “LM material” generally refers to a material including an LM that makes the composition electrically conductive once it is printed, dried, or cured. As used herein, the term “liquid metal” or “LM” generally refers to any metal or metal alloy that has a relatively low melting temperature under normal pressure and atmospheric conditions. For instance, a liquid metal can have a relatively low melting temperature that is within a range of about −30° C. to 100° C. In certain embodiments, a liquid metal is liquid at or near room temperature (e.g., from about 0° C. to about 40° C., or from about 10° C. to about 30° C.) in stressed or unstressed, deformed, or undeformed states.

As used herein, the term “alloy” refers to a mixture of two or more substances, with at least one substance being metal. For instance, an alloy can be a mixture of two or more metals, or a mixture of one or more metals and one or more non-metals. In certain embodiments, an alloy is a eutectic mixture, i.e., a mixture of two or more substances at specific proportions such that the mixture changes phase to liquid at a eutectic point relatively lower than a melting point of the pure substances. For instance, a eutectic gallium indium mixture (EGaIn) is composed of 75.5% Ga and 24.5% In by weight. EGaIn changes phase to liquid at about 15.7° C., which is lower than the gallium's melting point of about 29.8° C. and the indium's melting point of about 156.6° C.

In some embodiments, the liquid metal includes a pure substance, such as elemental indium (In), tin (Sn), bismuth (Bi), zinc (Zn), lead (Pb), gallium (Ga), aluminum (Al), lithium (Li) or the like. In other embodiments, the liquid metal includes an alloy made of at least one metal (e.g., In, Sn, Bi, Zn, Pb, Ga, Al, and/or Li) and at least one non-metal. Examples of nonmetals include, but are not limited to, silicon (Si), germanium (Ge), tellurium (Te), arsenic (As), or the like. In some embodiments, the liquid metal includes an alloy made of two or more metals. In some embodiments, the liquid metal includes an alloy made of two or more metals and one or more non-metals.

In certain embodiments, the liquid metal includes a gallium-based (Ga-based) alloy. For instance, in an embodiment, the liquid metal is a gallium indium alloy (e.g., eutectic GaIn), a gallium tin alloy, a gallium indium tin alloy (e.g., Galinstan), a gallium indium tin zinc alloy, or any combination thereof. In some embodiments, the gallium in the liquid metal is within a range of 25 to 95 percent by weight of the liquid metal. In an embodiment, the gallium-based alloy is Ga75.5In24.5, Ga67In20.5Sn12.5, Ga75.5In24.5, Ga61In25Sn13Zn1, or any combination thereof. Ga75.5In24.5 has a melting point of about 15.5° C., Ga67In20.5Sn12.5 has a melting point of about 10.5° C., and Ga61In25Sn13Zn1 has a melting point of about 7.6° C.

In certain embodiments, the liquid metal includes a bismuth-based alloy. For instance, in an embodiment, the liquid metal is a bismuth indium alloy, a bismuth indium tin alloy, or a bismuth indium tin zinc alloy. The bismuth in the liquid metal may be within a range of about 25 and 95 percent by weight of the liquid metal.

In some embodiments, the liquid metal includes more than one alloy. For instance, in an embodiment, the liquid metal includes both eutectic GaIn and Galinstan. In some embodiments, the liquid metal includes one or more other additional, optional or alternative substances. For instance, in an embodiment, the liquid metal includes a metal alloy made of copper along with one or more of gallium, indium, and/or tin.

The liquid metal material can have any suitable amount of the LM. For instance, in some embodiments, the liquid metal material includes the LM (e.g., a Ga-based alloy) at an amount from about 50% to about 60%, from about 60% to about 70%, from about 70% to about 80%, or from about 80% to about 90% by weight of the liquid metal material. In certain embodiments, the Ga-based alloy includes at least one of gallium indium alloy, gallium tin alloy, gallium indium tin alloy, or gallium indium tin zinc alloy. In some embodiments, the Ga-based alloy includes gallium at an amount within a range of about 50 wt % to about 85 wt % of the liquid metal material.

A deformable interconnect (e.g., the interconnect 340-1, 340-M, 350-1, 350-N) can be of any suitable shape and size. For instance, a deformable interconnect or a portion of it can be straight, curved, bent, and/or twisted. In some embodiments, a deformable interconnect has a height that is within a range of about 1 μm to 600 μm. In some embodiments, a deformable interconnect (e.g., the interconnect 340-1, 340-M, 350-1, 350-N) has a width that is within a range of about 1 μm to 600 μm. The deformable parts and deformable interconnects provide deformable electronic devices of the present disclosure with several advantages. For instance, they allow for configuring electronic devices that can function properly even when the devices are physically deformed. They allow for configuring electronic devices in various forms, shapes and/or sizes, with high complexity, and for use in various fields. The deformable interconnects of the present disclosure can maintain electrical communications when the deformable electronic devices are subjected to one or more certain conditions (e.g., strain, cycle, temperature, bending, etc.) and/or are physically deformed. In various embodiments, the deformable interconnects (e.g., liquid metal interconnects) of the present disclosure reduce cracking under cycling bending, stretching, thermal cycles, and/or other conditions that cause high stress concentrations to the solder joints at the interfaces, e.g., between a chip and a backplane flexible printed circuit (FPC). In some embodiments, the deformable interconnects of the present disclosure also relieve stress at the joints due to backplane or IC warpage.

In some embodiments, with the deformable part and deformable interconnects disclosed herein, a circuit of the deformable electronic device 300 can maintain conductivity with a resistance under a resistance threshold (e.g., a threshold that allows the deformable electronic device 300 to function properly) when the deformable electronic device 300 is subjected to one or more certain conditions (e.g., strain, cycle, temperature, bending, etc.). The resistance threshold may be at most 50 Ohms per cm (Ω/cm), at most 100 Ω/cm, or at most 150 Ω/cm.

In some embodiments, a circuit of the electronic part 330 maintains conductivity with a resistance under the resistance threshold when the deformable electronic device 300 is subject to a strain. As used herein, a strain (E) is defined as a function of a change in a gauge length (δ) against an original gauge length (L), such as: ε=δ/L. For instance, in some embodiments, a strain of X % means a change in length of a deformable part (e.g., the electronic part 330) as a function of an original length of the deformable part, where X is a number between 0 and 100. In some embodiments, the strain of X % means a change in width of the deformable part as a function of an original width of the deformable part. In some embodiments, the strain of X % means a change in depth of the deformable part as a function of an original depth of the deformable part. As a non-limiting example, if a deformable part has an original length of 10 cm and is subjected to 100% strain, the deformable part is to stretch to a new length of 20 cm. In some embodiments, the interposer 360 maintains conductivity with a resistance under the resistance threshold when the deformable electronic device 300 is subject to a strain within a range of about 20% to about 200%.

In some embodiments, a circuit of the electronic part 330 maintains conductivity with a resistance under the resistance threshold when the deformable electronic device 300 is subject to strain cycles. As used herein, a strain cycle refers to a process in which a strain is applied to the electronic part 330 in the first half of the cycle to stretch the electronic part 330 and then the strain is released in the second half of the cycle. For instance, a strain cycle of 100% cyclic strain and 5 second per cycle (i.e., a 5 second cycle under 100% strain) refers to a process in which a strain is applied in the first half of 5 seconds (2.5 seconds) to stretch the electronic part 330 to double its length or width and then the strain is released in the second half of 5 seconds. In some embodiments, the circuit maintains conductivity with a resistance under the resistance threshold when the deformable electronic device 300 is subject to a number of strain cycles within a range of 10 to 30,000 strain cycles of 100% strain.

In some embodiments, a circuit of the electronic part 330 maintains conductivity with a resistance under the resistance threshold when the deformable electronic device 300 is subject to a temperature (e.g., the deformable electronic device 300 is used or placed in an environment at the temperature). In some embodiments, the temperature is within a range of about −30° C. to about 155° C. In some embodiments, when the deformable electronic device 300 is subjected to one or more certain conditions (e.g., strain, cycle, temperature, bending, etc.), a circuit of the electronic part 330 maintains conductivity corresponding to a resistance within a range of about 0.1 Ω/cm to about 150 Ω/cm.

In some embodiments, a deformable interconnect (e.g., the interconnect 340-1, 340-M, or 340-N) is free of degradation in conductivity when the electronic part 330 is bent, e.g., around a cylinder or the like, for a period of time and then released. In some embodiments, each deformable interconnect (e.g., the interconnects 340, 350) is free of degradation in conductivity when the electronic part 330 is bent, e.g., around a cylinder or the like, for a period of time and then released. In some embodiments, the bending radius is within a range of about 1 cm to about 25 cm. In some embodiments, the bending radius is similar or substantially similar to a size of a human wrist (e.g., from about 4 cm to about 10 cm). The period of time may be seconds, minutes, hours, days, weeks, or months.

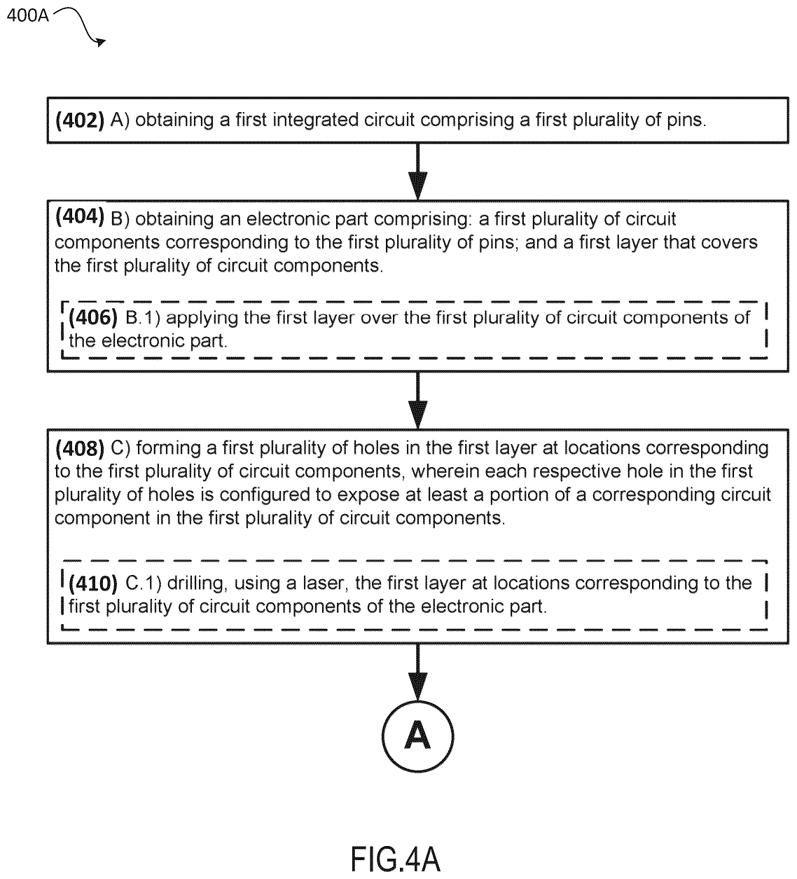

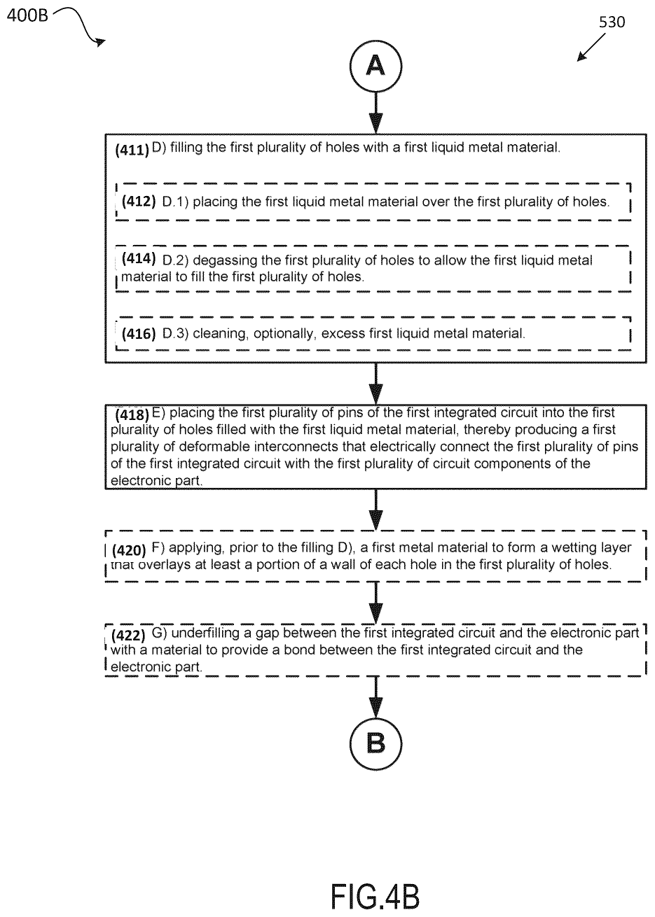

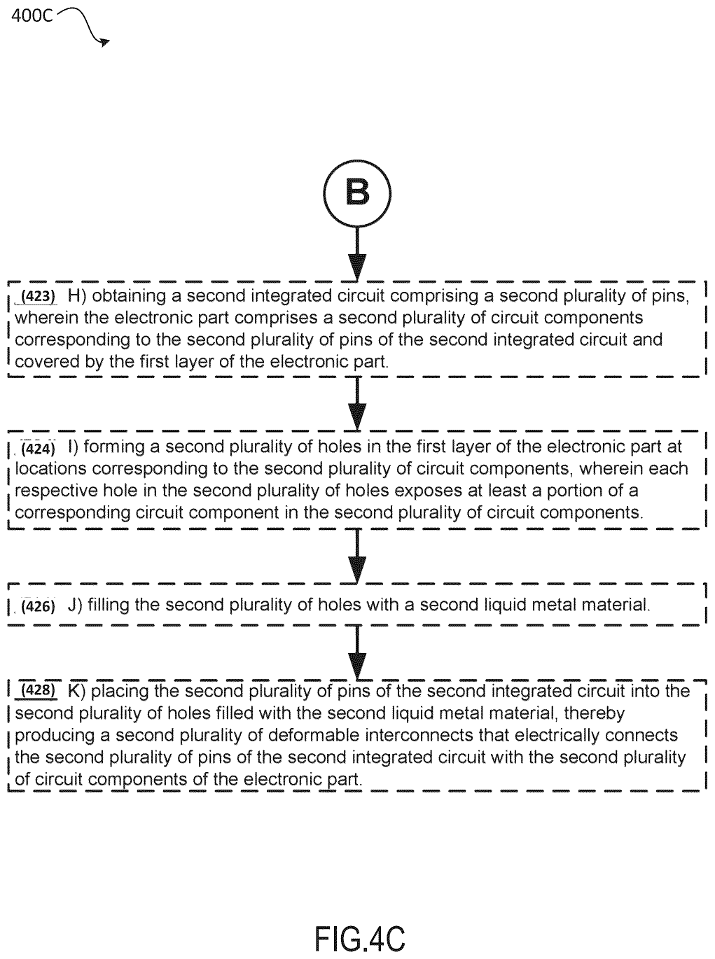

FIGS. 4A, 4B and 4C are flow diagrams 400A, 400B and 400C collectively illustrating an exemplary method for forming deformable electrical devices (e.g., 300 of FIG. 3), in accordance with some embodiments of the present disclosure. In the flow diagrams 400A, 400B and 400C, the optional elements of embodiments are indicated by dashed boxes and/or lines. The flow diagram 400A starts at operation block 402, where a first IC including a first plurality of contacts and/or pins is obtained. At operation block 404, an electronic part including a first plurality of circuit components corresponding to the first plurality of contacts and/or pins and a first layer that covers the first plurality of circuit components are obtained. At optional operation block 406, the first layer is applied over the first plurality of circuit components of the electronic part. At operation block 408, a first plurality of holes are formed in the first layer at locations corresponding to the first plurality of circuit components, wherein each respective hole in the first plurality of holes is configured to expose at least a portion of a corresponding circuit component in the first plurality of circuit components. At an optional operation block 410, using a laser, the first layer at locations corresponding to the first plurality of circuit components of the electronic part is drilled. In some implementations, drilling may be replaced by other methods of patterning. In some implementations, the drilling may be precluded if the LM material has sufficient viscosity.

The flow diagram 400B starts at optional operation block 411, where the first plurality of holes are filled with a first LM material. At optional operation block 412, the first LM material is placed over the first plurality of holes. At optional operation block 414, the first plurality of holes are degassed to allow the first LM material to fill the first plurality of holes. At optional operation block 416, excess first LM material is cleaned. At operation block 418, the first plurality of contacts and/or pins of the first IC are placed into the first plurality of holes filled with the first liquid metal material, thereby producing a first plurality of deformable interconnects that electrically connect the first plurality of contacts and/or pins of the first IC with the first plurality of circuit components of the electronic part. At optional operation block 420, prior to the filling at operation block 411, a first metal material is applied to form a wetting layer that overlays at least a portion of a wall of each hole in the first plurality of holes. At optional operation block 422, a gap between the first IC and the electronic part is underfilled with a material to provide a bond between the first IC and the electronic part.

The flow diagram 400C includes optional operation blocks and starts at optional operation block 423, where a second IC including a second plurality of contacts and/or pins is obtained, wherein the electronic part includes a second plurality of circuit components corresponding to the second plurality of contacts and/or pins of the second IC and covered by the first layer of the electronic part. At optional operation block 424, a second plurality of holes are formed in the first layer of the electronic part at locations corresponding to the second plurality of circuit components, wherein each respective hole in the second plurality of holes exposes at least a portion of a corresponding circuit component in the second plurality of circuit components. At optional operation block 426, the second plurality of holes are filled with a second liquid metal material. Finally, at optional operation block 428, the second plurality of contacts and/or pins of the second IC are placed into the second plurality of holes filled with the second liquid metal material, thereby producing a second plurality of deformable interconnects that electrically connects the second plurality of contacts and/or pins of the second integrated circuit with the second plurality of circuit components of the electronic part.

In some embodiments, the operation blocks 408 and 424 are conducted concurrently. Alternatively, in some embodiments, the operation blocks 408 and 424 are conducted sequentially.

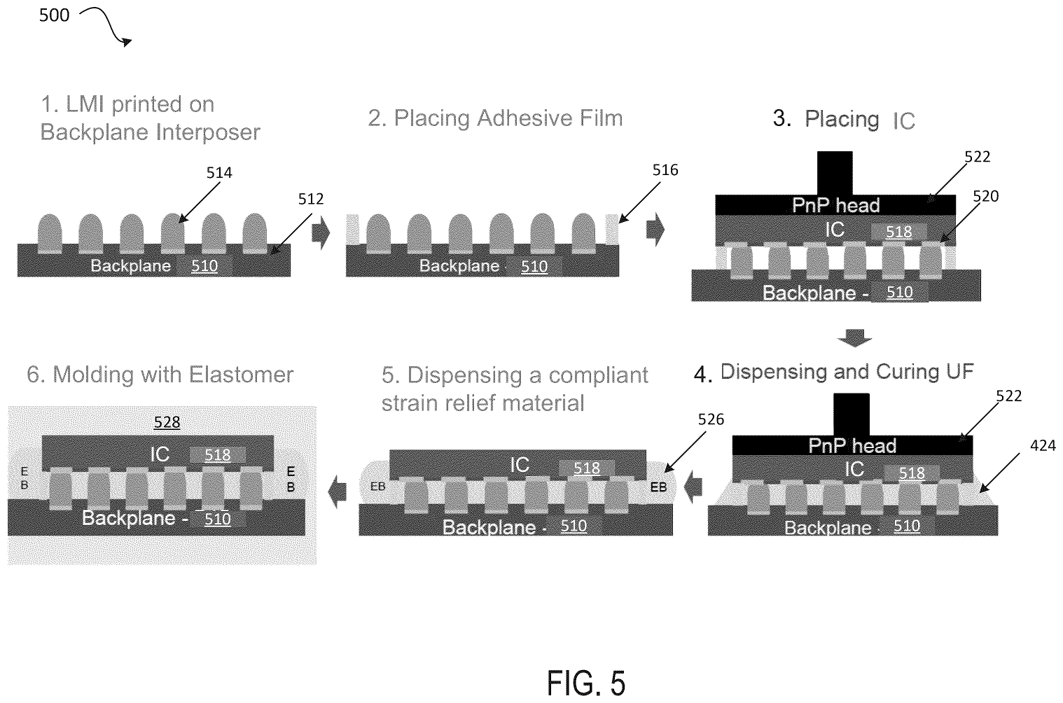

FIG. 5 is a process flow diagram illustrating an example of a method 500 for forming deformable electrical devices, in accordance with some embodiments of the present disclosure. The method 500 includes process steps 1 through 6.

In step 1, copper pads 512 are formed and then coated with electroless nickel, immersion gold (ENIG) and LM composites (e.g., LM silver bumps) 514 are created on a backplane 510. Each of pads 512 includes a nickel layer of about a couple of microns and on the top of it a layer of gold with a thickness of about 100 nanometers.

In step 2, adhesive films such as pressure sensitive adhesive (PSA) tapes 516 are placed as standoffs. In some implementations, two different methods for PSA placement can be used, one on the IC 518 and the other using a jig on the backplane.

In step 3, IC 518 including a number of contact pads 520 is placed on top of the structure formed in step 2 using a pick-and-place (PnP) 522. The contact pads 520 are aligned with the LM interconnects or LM-patterned interconnects such as LM composites (e.g., silver bumps) 514.

Step 4 is a dispensing and curing underfill (UF) step, where UF 424 is applied and cured.

Step 5 is a dispensing compliant strain relief material step, where the PnP 522 is removed and the compliant strain relief material such as (electronic bonding (EB) 526 is formed.

In step 6, an elastomer such as silicone is used to mold the entire structure formed in step 5 by a silicone mold layer 528.

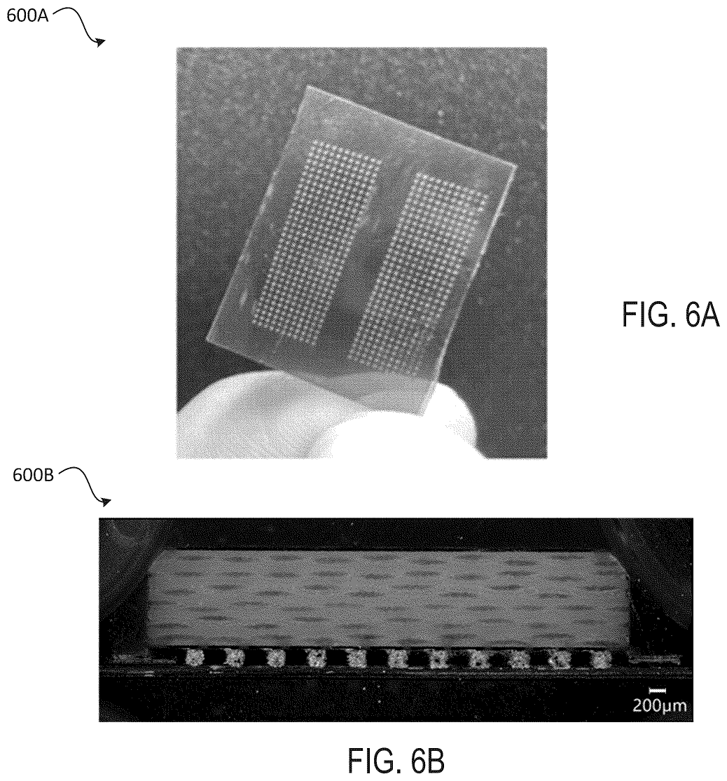

FIGS. 6A and 6B are top view 600A and cross-sectional view 600B illustrating an example of a stack of vias 600, in accordance with some embodiments of the present disclosure. The stack of vias 600 can be made by the method 500 of FIG. 5. The stack of vias 600 is made using a dielectric (PI) substrate. A plurality of holes is formed on the substrate, for instance, using LM interconnects in a pre-patterned dielectric. The substrate is cleaned, for instance, placed in isopropyl alcohol (IPA) for 20 minutes and plasma 200 W for 3 minutes. A liquid metal material is disposed on top of the plurality of holes, and the substrate is placed in a vacuum for 10 minutes. Excess of the liquid material is removed with squeegee. The substrate is capped, for instance, with a film including 12.5 μm/12.5 μm PI/adhesive.

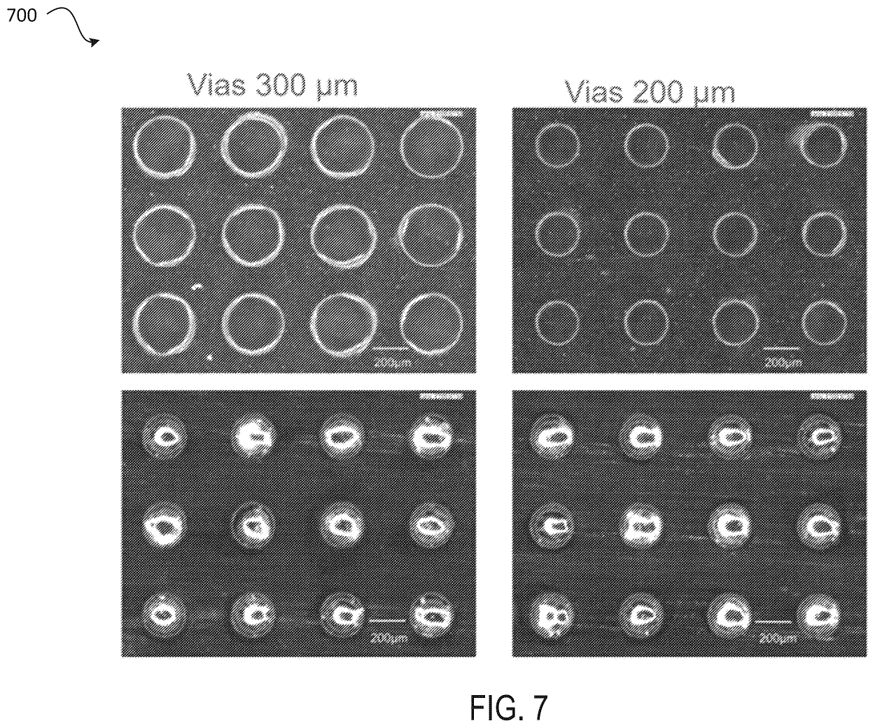

FIG. 7 is a schematic diagram illustrating various vias 700, in accordance with some embodiments of the present disclosure. Vias 700 are deformable interconnects with diameters of 200 μm and 300 μm and are created by the method 500 of FIG. 5.

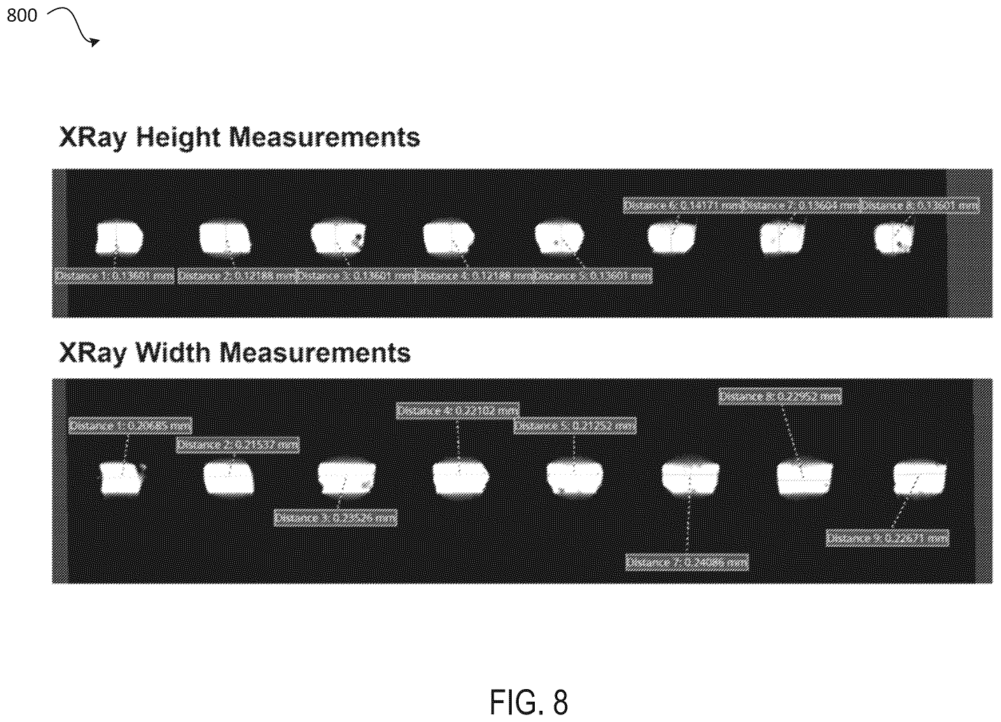

FIG. 8 is a schematic diagram illustrating Xray height and width measurements of various vias 800, in accordance with some embodiments of the present disclosure. Vias 800 are deformable interconnects and are created by the method 500 of FIG. 5.

FIGS. 9A and 9B are schematic diagrams illustrating examples of designs 900A and 900B of contacts and/or pins 910 for an IC (e.g., SMD 310-1 and 310-2 of FIG. 3), in accordance with some embodiments of the present disclosure.

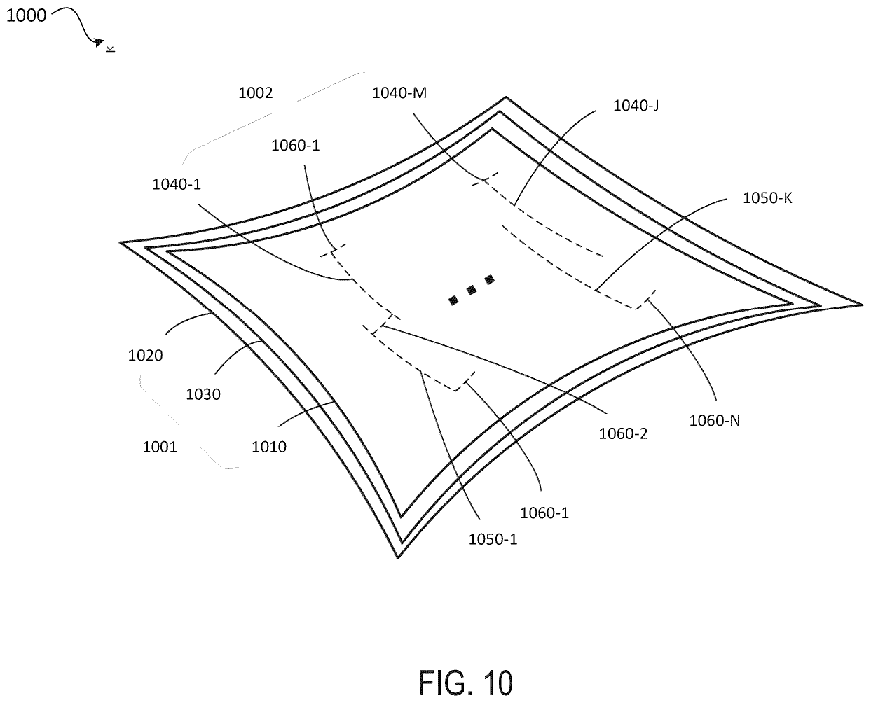

FIG. 10 is a schematic diagram illustrating an example of a deformable electronic device 1000, in accordance with some embodiments of the present disclosure. The deformable electronic device 1000 generally includes a deformable substrate having a plurality of layers and one or more deformable circuits disposed in multiple layers of the deformable substrate. For instance, as a non-limiting example, FIG. 10 illustrates the deformable electronic device 1000 including the substrate 1001 and a multi-layer deformable circuit 1002.

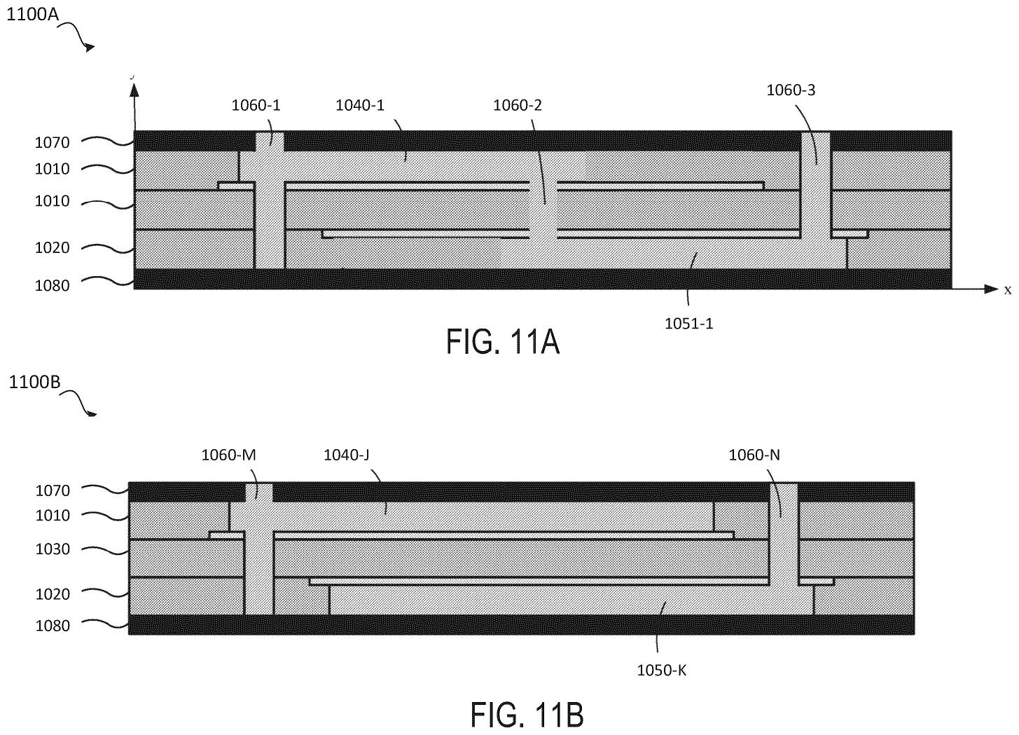

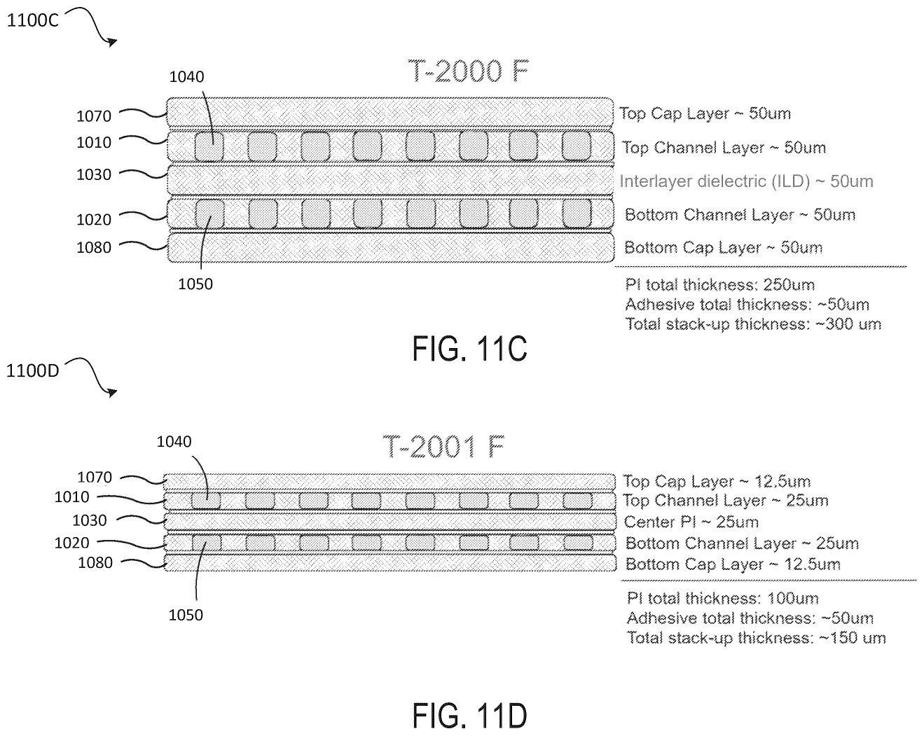

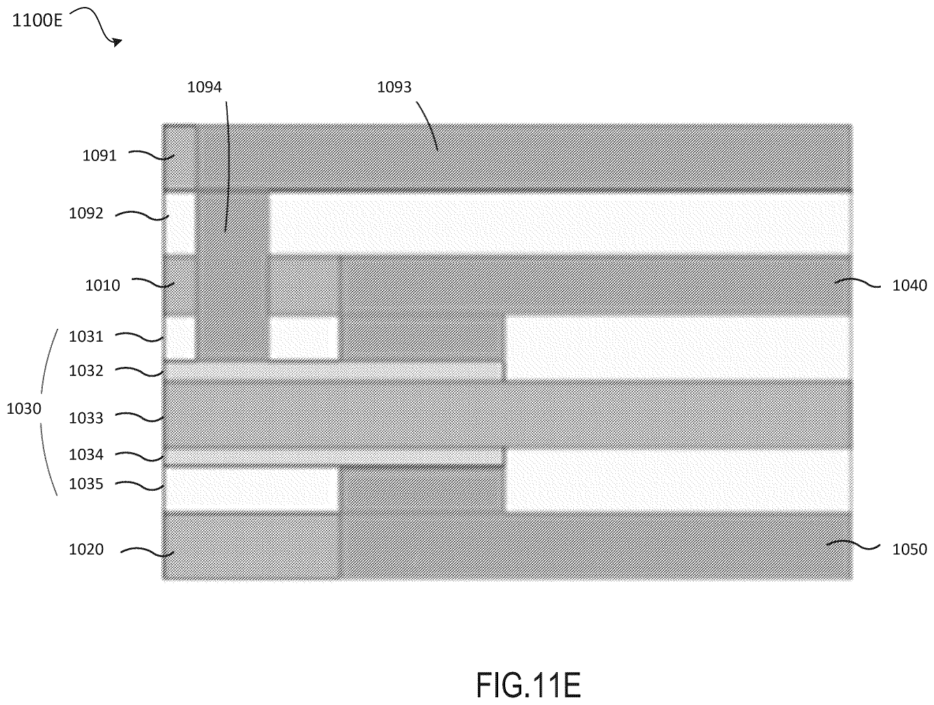

In some embodiments, the substrate 1001 includes a first layer 1010, a second layer 1020, and at least one middle layer 1030 sandwiched between the first and second layers. The middle layer(s) 1030 can include 1, 2, 3, 4, 5, or more than 5 layers. For instance, as a non-limiting example, FIG. 11E illustrates that the at least one middle layer 1030 includes a dielectric layer 1033, two cupper layers 1032 and 1034, and two adhesive layers 1031 and 1035 for coupling the first layer 1010 and the second layer 1020 with the at least one middle layer 1030. In some embodiments, the first layer 1010 or at least a portion of it is made of a material including dielectric and accordingly is referred to herein as the first dielectric layer. Similarly, in some embodiments, the second layer 1020 or at least a portion of it is made of a material including dielectric and accordingly is referred to herein as the second dielectric layer. In some embodiments, the at least one middle layer 1030 includes a layer or a portion of it made of a material including dielectric and accordingly is referred to herein as the at least one middle dielectric layer 1030. However, the present disclosure is not limited thereto. A layer (e.g., the first layer 1010 or the second layer 1020) of the substrate 1001 can be made of other materials.

In some embodiments, the multi-layer deformable circuit 1002 includes a first plurality of deformable LM traces 1040-1, . . . 1040M . . . 1040-J, a second plurality of deformable LM traces 1050-1, . . . , 1050-K, a plurality of deformable LM vias 1060-1, 1060-2, . . . 1060-M . . . 1060-N, or any combination thereof. The first plurality of deformable LM traces 1040 is disposed in the first layer 1010 and the second plurality of deformable LM traces 1050 is disposed in the second layer 1020. Each respective deformable LM via in the plurality of deformable LM vias 1060 is in electrical communication with at least one of (i) a corresponding deformable LM trace in the first plurality of deformable LM traces 1040 and (ii) a corresponding deformable LM trace in the second plurality of deformable LM traces 1050 across the middle layer(s) 1030.

FIGS. 11A, 11B, 11C, 11D, and 11E are schematic cross-sectional views 1100A, 1100B, 1100C, 1100D and 1100E of a deformable electronic device 1000 of FIG. 10, in accordance with some exemplary embodiments of the present disclosure. The cross-sectional view 1100A of FIG. 11A illustrates that the deformable LM trace 1040-1 is disposed in the first layer 1010 and the deformable LM trace 1050-1 is disposed in the second layer 1020. The deformable LM via 1060-1 is in electrical communication with the deformable LM trace 1040-1. The deformable LM via 1060-3 is in electrical communication with the deformable LM trace 1050-1. The deformable LM via 1060-2 is in electrical communication with both the deformable LM trace 1040-1 and the deformable LM trace 1050-1.

The cross-sectional view 1100B of FIG. 11B illustrates that the deformable LM trace 1040-J is disposed in the first layer 1010 and the deformable LM trace 1050-K is disposed in the second layer 1020. The deformable LM via 1060-M is in electrical communication with the deformable LM trace 1040-J, and the deformable LM via 1060-N is in electrical communication with the deformable LM trace 1050-K. In some embodiments, the substrate 1001 of FIG. 10 includes one or more additional or optional layers. For instance, as a non-limiting example, FIGS. 11A and 111B illustrate that the substrate 1001 includes a first cap layer 1070 and a second cap layer 1080. The first cap layer 1070 is disposed on the first layer 1010 and the second cap layer 1080 is disposed on the second layer 1020 to cover at least some of the first plurality of deformable LM traces 1040, the second plurality of deformable LM traces 1050 and the plurality of deformable LM vias 1060.

The cross-sectional view 1100C of FIG. 11C illustrates a deformable electronic device including an exemplary substrate 1001, referred to herein as T-2000 F, in which each of the first layer 1010, the second layer 1020, the middle layer(s) 1030, the first cap layer 1070 and the second cap layer 1080 has a thickness of about 50 μm. These layers are stacked together using an adhesive with a total thickness of about 50 μm. This results in the deformable electronic device 1000 having the total stack-up thickness of about 300 μm.

The cross-sectional view 1100D of FIG. 11D illustrates a deformable electronic device including another exemplary substrate 1001, referred to herein as T-2001 F, in which each of the first layer 1010, the second layer 1020, and the at least one middle layer 1030 has a thickness of about 25 μm while each of the first cap layer 1070 and the second cap layer 1080 has a thickness of about 12.5 μm. These layers are stacked together using an adhesive with a total thickness of about 50 μm. This results in the deformable electronic device 1000 having the total stack-up thickness of about 150 μm.

The cross-sectional view 1100E of FIG. 11E illustrates that the substrate 1001 includes a third layer 1091 attached to the first layer 1010, for instance, by an adhesive 1092. In some embodiments, the multi-layer deformable circuit 1002 includes one or more deformable LM traces 1093 disposed in the third layer 1091. In some embodiments, the multi-layer deformable circuit 1002 of FIG. 10 includes one or more deformable LM vias 1094 in electrical communication with the one or more deformable LM traces 1093, the first plurality of deformable LM traces 1040, the second plurality of deformable LM traces 1050, and/or other components of the deformable electronic device 1000. In some embodiments, the first layer 1010 has a thickness (e.g., the dimension of the first layer along the y-direction in FIG. 11A) of between 15 microns (μm) and 60 μm. In some embodiments, the first layer 1010 has a thickness within a range of about 5 μm to about 60 μm.

The second layer 1020 can have the same thickness as the first layer 1010 or a different thickness than the first layer 1010. In some embodiments, the second layer 1020 has a thickness (e.g., the vertical dimension of the second layer in FIG. 11A or 11B) of between 15 μm and 60 μm. In some embodiments, the second layer 1020 has a thickness within a range of about 5 μm to 60 μm.

In some embodiments, the middle layer(s) 1030 has a thickness of between 15 μm and 60 μm. In some embodiments, the second layer 1020 has a thickness that is within a range of about less than about 50 μm, less than about 45 μm, less than about 40 μm, and less than about 5 μm to 35 μm.

In some embodiments, the optional or additional first cap layer 1070 has a thickness of between 5 μm and 60 μm. In some embodiments, the optional or additional first cap layer 1070 has a thickness of 10 μm.

The optional or additional second cap layer 1080 can have a thickness the same as the first cap layer 1070 or a different thickness than the first cap layer 1070. In some embodiments, the optional or additional second cap layer 1080 has a thickness within a range of about 10 μm to about 60 μm. The substrate 1001 typically has a thickness of 350 μm or less. In some embodiments, the substrate 1001 has a thickness within a range of about 150 μm to about 325 μm.

Each trace in the first plurality of deformable LM traces 1040 and the second plurality of deformable LM traces 1050 has a length (e.g., the nominal dimension along the y-direction in FIG. 11A, a depth (e.g., the nominal dimension along the direction in FIG. 11A), and a width (e.g., the nominal dimension along a direction perpendicular to the x-y plane in FIG. 11A).

Different traces in the first plurality of deformable LM traces 1040 and the second plurality of deformable LM traces 1050 can be identical to each other, e.g., having the same length, depth, and width, or different from each other, e.g., having at least one difference in length, depth and/or width. In addition, traces in the first plurality of deformable LM traces 1040 and the second plurality of deformable LM traces 1050 can be disclosed close to each other or away from each other.

In some embodiments, at least one trace in the first plurality of deformable LM traces 1040 or the second plurality of deformable LM traces 1050 has a depth of between 15 μm and 60 μm. In some embodiments, each trace in the first plurality of deformable LM traces 1040 or the second plurality of deformable LM traces 1050 has a depth of between 15 μm and 60 μm. In some embodiments, each trace in the first plurality of deformable LM traces 1040 or the second plurality of deformable LM traces 1050 has a depth within a range of about 5 μm to about 60 μm.

In some embodiments, at least one trace in the first plurality of deformable LM traces 1040 or the second plurality of deformable LM traces 1050 has a width of between 15 μm and 200 μm. In some embodiments, each trace in the first plurality of deformable LM traces 1040 or the second plurality of deformable LM traces 1050 has a width within a range of about 15 μm and 200 μm.

In some embodiments, at least one trace in the first plurality of deformable LM traces 1040 or the second plurality of deformable LM traces 1050 has a width within a range from 5 μm to 100 μm. In some embodiments, at least one trace in the first plurality of deformable LM traces 1040 or the second plurality of deformable LM traces 1050 has a length within a range of about 3 mm to about 100 mm.

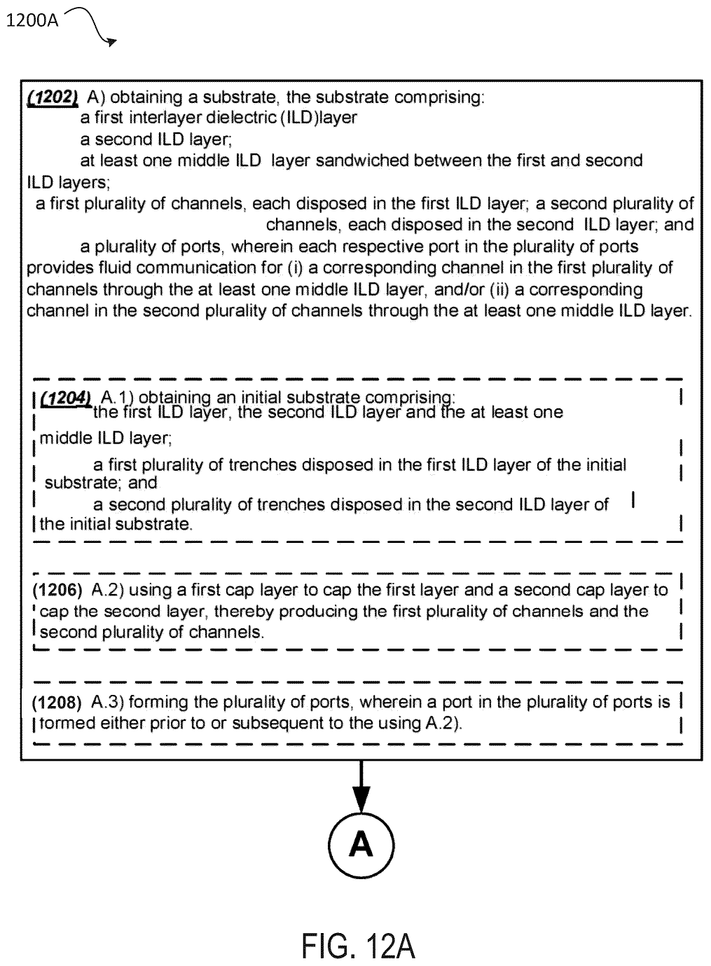

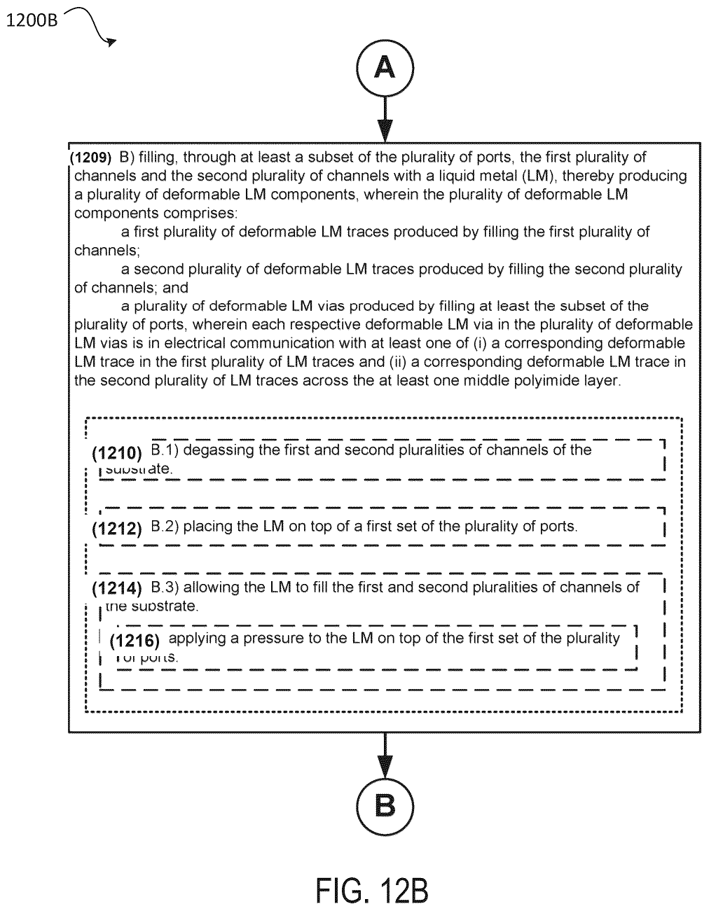

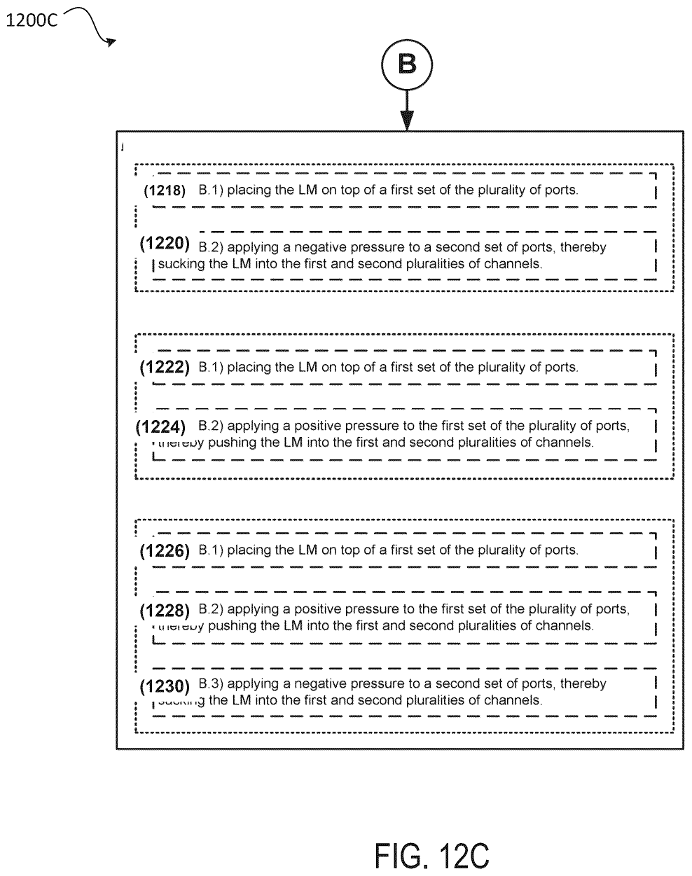

FIGS. 12A, 12B, and 12C are flow charts 1200A, 1200B, 1200C collectively illustrating a method for manufacturing an electronic device, in accordance with some embodiments of the present disclosure. The flow chart 1200A starts at operation block 1202 where a substrate having a thickness of about 350 μm or less is obtained. The substrate includes: a first dielectric layer having a thickness of between 15 μm and 60 μm; a second dielectric layer having a thickness of between 15 μm and 60 μm; at least one middle dielectric layer sandwiched between the first and second dielectric layers, wherein the at least one middle dielectric layer collectively has a thickness of between 15 μm and 60 μm; a first plurality of channels, each disposed in the first dielectric layer; a second plurality of channels, each disposed in the second dielectric layer; and a plurality of ports, wherein each respective port in the plurality of ports provides fluid communication for (i) a corresponding channel in the first plurality of channels through the at least one middle dielectric layer, and/or (ii) a corresponding channel in the second plurality of channels through the at least one middle dielectric layer.

At optional operation block 1204, an initial substrate is obtained. The substrate includes the first dielectric layer, the second dielectric layer and the at least one middle dielectric layer, a first plurality of trenches disposed in the first dielectric layer of the initial substrate, and a second plurality of trenches disposed in the second dielectric layer of the initial substrate.

At optional operation block 1206, using a first cap layer to cap the first layer and a second cap layer to cap the second layer, the first plurality of channels and the second plurality of channels are produced.

At optional operation block 1208, the plurality of ports are formed, wherein a port in the plurality of ports is formed either prior to or subsequent to the using the operation block 1206. In some embodiments, the plurality of ports is formed through the first cap layer, the second cap layer, or both.

The flow chart 1200B starts at operation block 1209 where the first plurality of channels and the second plurality of channels are filled, through at least a subset of the plurality of ports, with an LM, thereby producing a plurality of deformable LM components. The plurality of deformable LM components includes: a first plurality of deformable LM traces produced by filling the first plurality of channels; a second plurality of deformable LM traces produced by filling the second plurality of channels; and a plurality of deformable LM vias produced by filling at least the subset of the plurality of ports, wherein each respective deformable LM via in the plurality of deformable LM vias is in electrical communication with at least one of (i) a corresponding deformable LM trace in the first plurality of LM traces and (ii) a corresponding deformable LM trace in the second plurality of LM traces across the at least one middle dielectric layer. In some embodiments, the filling of operation block 1209 is conducted using vacuum, pressure, suction, injection, or any combination thereof.

In some embodiments, the filling of operation block 1209 includes optional operation block 1210, where the first and second pluralities of channels of the substrate are degassed. In some embodiments, the filling of operation block 1209 includes optional operation block 1212, where the LM is placed on top of a first set of the plurality of ports. In some embodiments, the filling of operation block 1209 includes optional operation block 1214, where the LM is allowed to fill the first and second pluralities of channels of the substrate. In some embodiments, the filling of operation block 1209 includes optional operation block 1216, where a pressure is applied to the LM on top of the first set of the plurality of ports. In an exemplary embodiment, the applying of a pressure is conducted by placing the substrate with the LM on top of the first set of ports in a pressure pot.

The flow chart 1200C starts at optional operation block 1218 where the filling of operation block 1209 continues by placing the LM on top of a first set of the plurality of ports.

In some embodiments, the filling of operation block 1209 includes optional operation block 1220, where a negative pressure is applied to a second set of ports, thereby pulling the LM into the first and second pluralities of channels.

In some embodiments, the filling of operation block 1209 includes optional operation block 1222, where the LM is placed on top of a first set of the plurality of ports. In some embodiments, the filling of operation block 1209 includes optional operation block 1224, where a positive pressure is applied to the first set of the plurality of ports, thereby pushing the LM into the first and second pluralities of channels.

In some embodiments, the filling of operation block 1209 includes optional operation block 1226, where the LM is placed on top of a first set of the plurality of ports. In some embodiments, the filling of operation block 1209 includes optional operation block 1228, where a positive pressure is applied to the first set of the plurality of ports, thereby pushing the LM into the first and second pluralities of channels. In some embodiments, the filling of operation block 1209 includes optional operation block 1230, where a negative pressure is applied to a second set of ports, thereby pulling the LM into the first and second pluralities of channels. In an exemplary embodiment, the applying of the positive pressure and the applying of the negative pressure are conducted concurrently. In another exemplary embodiment, the applying of the positive pressure and the applying of the negative pressure are conducted sequentially or overlapping.

In some embodiments, the substrate with the plurality of deformable LM components has a bending stiffness within a range of about 2 N/cm to 15 N/cm. In some embodiments, a deformable LM component in the plurality of deformable LM components has a width within a range from 5 μm to 200 μm. In some embodiments, a deformable LM component in the plurality of deformable LM components has a height within a range from 5 μm to 100 μm. In some embodiments, a deformable LM component in the plurality of deformable LM components has a length within a range from 5 mm to 100 mm. In some embodiments, the middle dielectric layer includes two, three, four, five, or more than five layers. In some embodiments, the middle dielectric layer includes at least one patterned copper layer, at least one adhesive layer, at least one Pi layer, or any combination thereof.

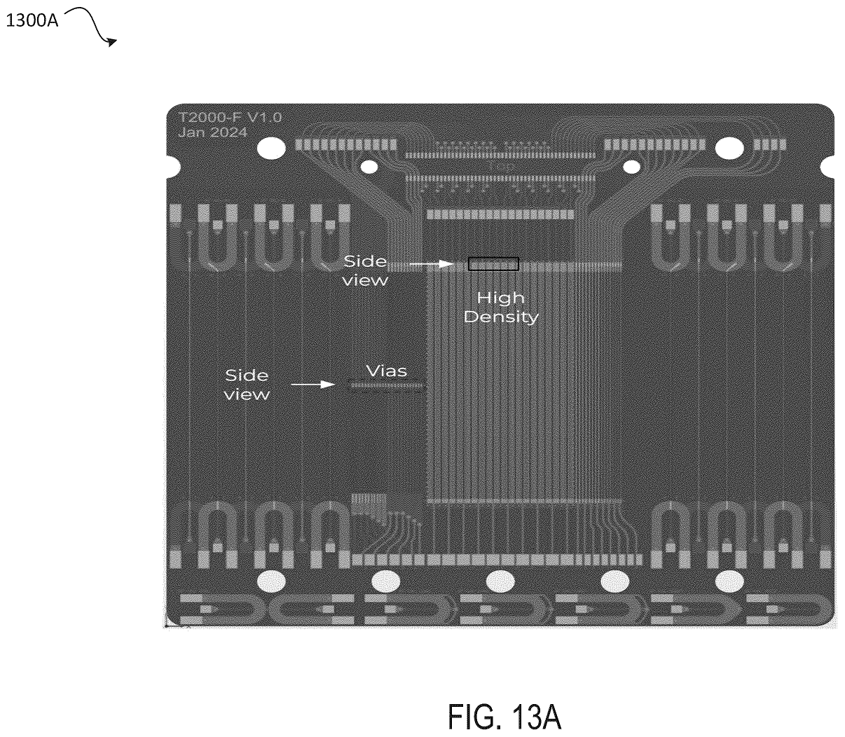

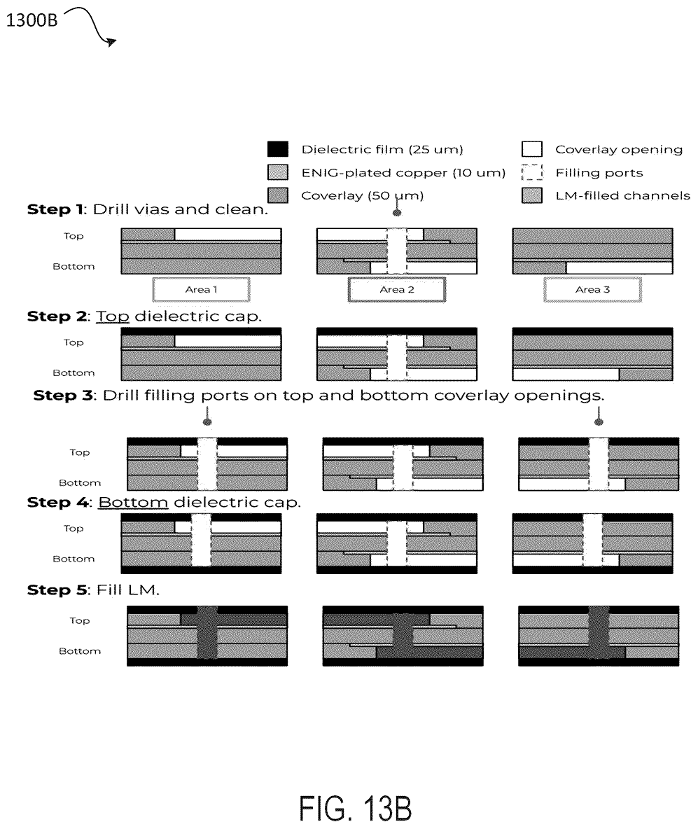

FIG. 13A is a schematic diagram illustrating an example of a substrate 1300A, in accordance with some exemplary embodiments of the present disclosure. The substrate 1300A is an example of the initial substrate obtained in the operation blocks of the method shown and discussed above with regard to the flow charts of FIGS. 12A, 12B, and 12C above.

FIG. 13B is a process flow diagram illustrating an example of a method 1300B for forming deformable electrical devices, in accordance with some embodiments of the present disclosure. FIG. 13B provides schematic side views of a region (e.g., the “Vias” region) of the initial substrate of FIG. 13A, illustrating an exemplary process flow in accordance with some exemplary embodiments of the present disclosure. Method 1300B includes Steps 1 through 5 as discussed below.

In particular, FIG. 13B illustrates the initial substrate having a first layer (e.g., the top layer), a second layer (e.g., the bottom layer), and the at least one middle layer (e.g., the layer(s) sandwiched between the top and bottom layers). At Step 1, a trench (referred in the figure as “Coverlay opening”) is disposed in the first layer of the initial substrate, and a trench is disposed in the second layer of the initial substrate. Also, at Step 1, a filling port is drilled in Area 2 to connect the trench disposed in the first layer and the trench disposed in the second layer of the initial substrate. Step 1 further includes cleaning, optionally or additionally, the substrate after the drilling.

At Step 2, the first layer is covered with a first cap layer (referred in the figure as “Top EKJ cap”). Covered by the first cap layer, the trench disposed in the first layer forms a channel in the first layer.

At Step 3, a filling port is drilled in Area 1 to provide fluid communication for the trench disposed in the first layer and a filling port in Area 3 to provide fluid communication for the trench disposed in the second layer.

At Step 4, the second layer is covered with a second cap layer (referred in the figure as “Bottom EKJ cap”). Covered by the second cap layer, the trench disposed in the second layer forms a channel in the second layer.

At Step 5, the channel is filled with LM. This provides a substrate with a channel in the first layer, a channel in the second layer, a port in Area 1 that provides fluid communication for the channel in the first layer, a port in Area 3 that provides fluid communication for the channel in the second layer, and a port in Area 2 that provides fluid communication for both the channel in the first layer and the channel in the second layer.

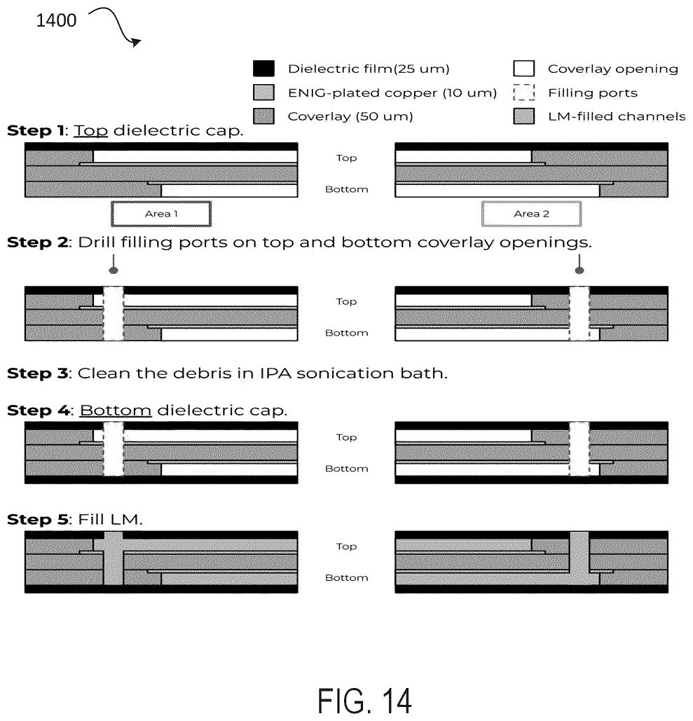

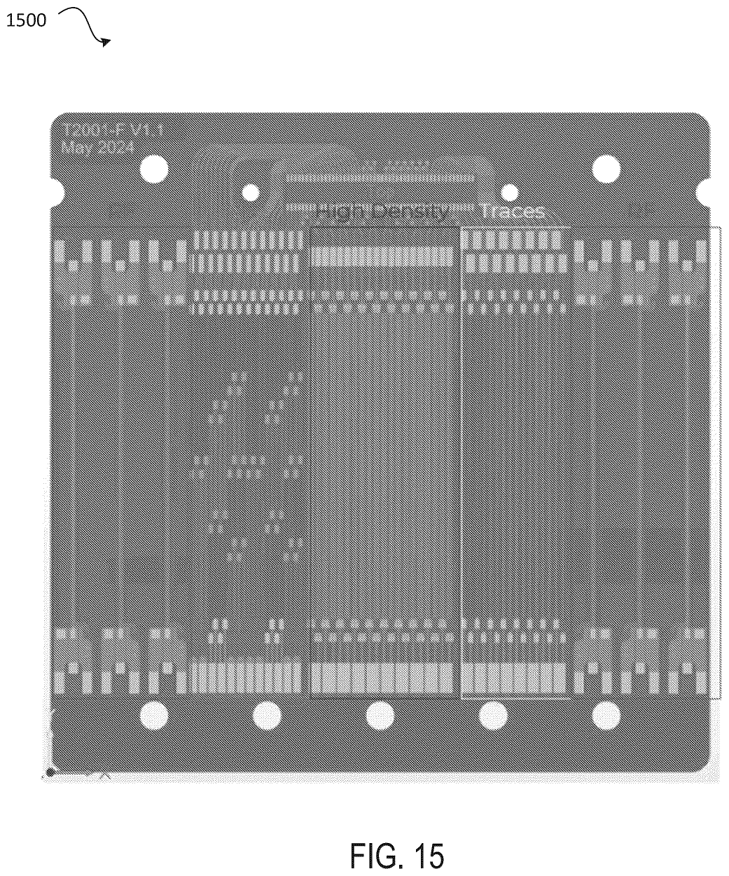

FIG. 14 is a process flow diagram illustrating an example of a method 1400 for forming deformable electrical devices, in accordance with some embodiments of the present disclosure. FIG. 14 illustrates the initial substrate having a first layer (e.g., the top layer), a second layer (e.g., the bottom layer), and the at least one middle layer (e.g., the layer(s) sandwiched between the top and bottom layers). At Step 1, a trench (referred in the figure as “Coverlay opening”) is disposed in the first layer of the initial substrate, and a trench is disposed in the second layer of the initial substrate. Step 1 also includes covering the first layer with a first cap layer (referred in the figure as “Top laminate dielectric film cap”). Covered by the first cap layer, the trench disposed in the first layer forms a channel in the first layer.

At Step 2, a filling port is drilled in Area 1 to provide fluid communication for the trench disposed in the first layer and a filling port in Area 2 to provide fluid communication for the trench disposed in the second layer.

At Step 3, the substrate is, optionally or additionally, cleaned such as the debris in an IPA sonication bath.

At Step 4, the second layer is covered with a second cap layer (referred in the figure as “Bottom laminate dielectric film cap”). Covered by the second cap layer, the trench disposed in the second layer forms a channel in the second layer.

The first layer of the “Vias” region and the first layer of the “High Density/Traces/RF” region may be covered by a single first cap layer in Step 2 and Step 1. Alternatively, the first layer of the “Vias” region and the first layer of the “High Density/Traces/RF” region may be covered by different first cap layers. Similarly, the second layer of the “Vias” region and the second layer of the “High Density/Traces/RF” region may be covered by a single second cap layer in Step 4. Alternatively, the second layer of the “Vias” region and the second layer of the “High Density/Traces/RF” region may be covered by different second cap layers. In addition, the drilling in Step 3 and the drilling in Step 2 may be formed concurrently, subsequently or overlapping.

At Step 5, the LM is filled through the port in Area 1, the port in Area 3, or both. This produces two deformable LM traces and three vias: a deformable LM trace in the first layer, a deformable LM trace in the second layer, a via in Area 1 that is in electrical communication with the deformable LM trace in the first layer, a via in Area 3 that is in electrical communication with the deformable LM trace in the second layer, and a via in Area 2 that is in electrical communication with both the deformable LM trace in the first layer and the deformable LM trace in the second layer.

As another non-limiting example, at Step 5, the LM is filled through the port in Area 1 and the port in Area 2. This provides two deformable LM traces and two vias: a deformable LM trace in the first layer, a deformable LM trace in the second layer, a via in Area 1 that is in electrical communication with the deformable LM trace in the first layer, and a via in Arca 2 that is in electrical communication with the deformable LM trace in the second layer.

FIG. 15 is a schematic diagram illustrating an example of a substrate 1500, in accordance with some exemplary embodiments of the present disclosure. The substrate 1500 includes high density traces.

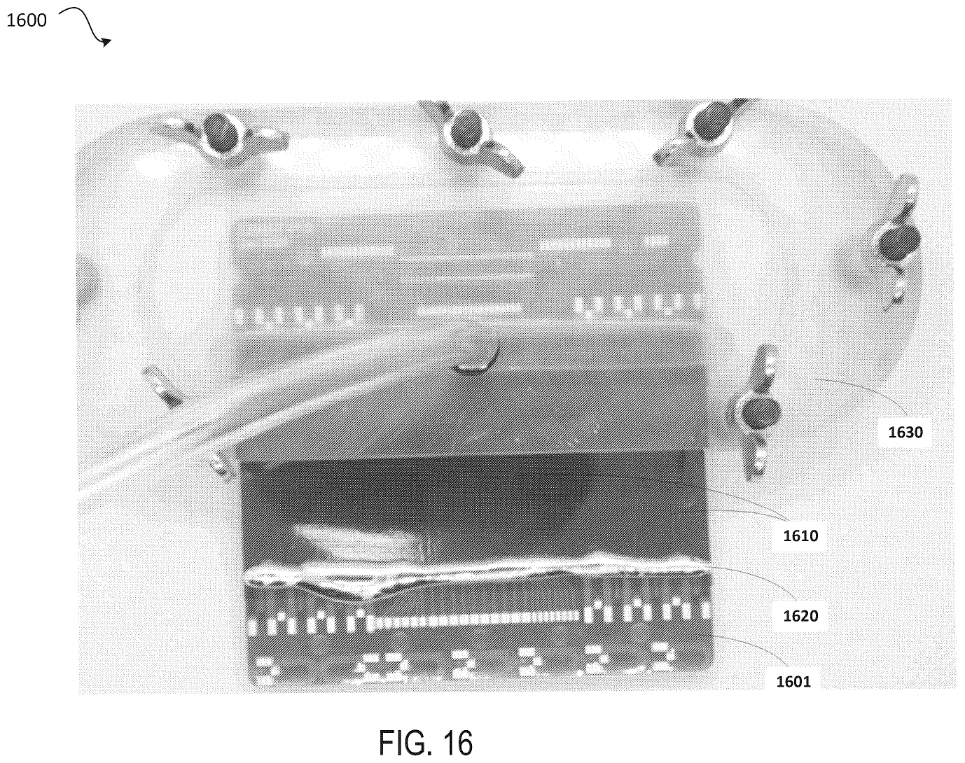

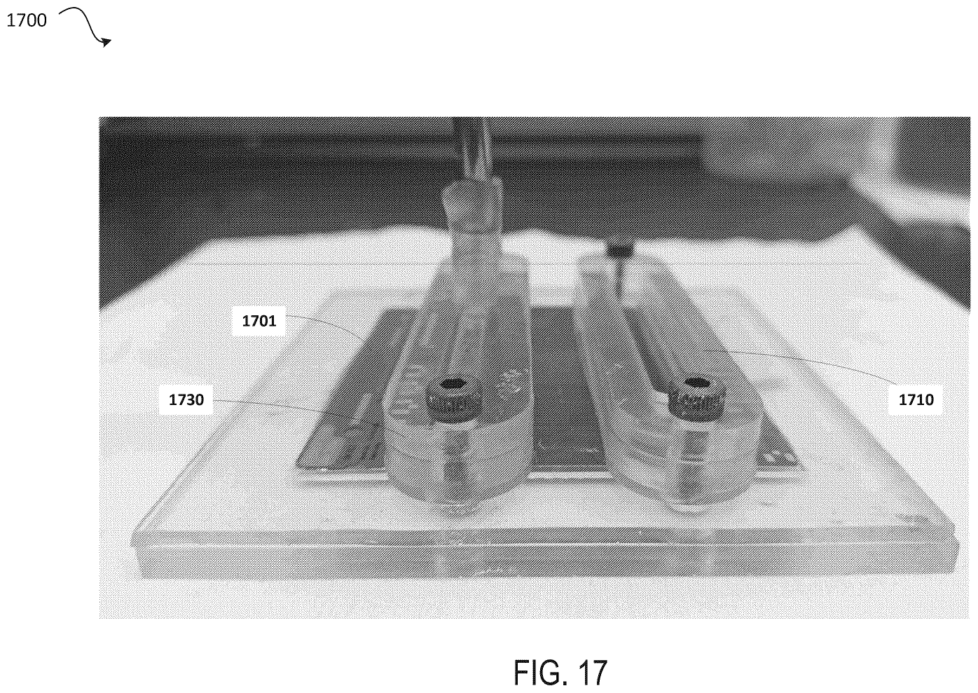

FIG. 16 is a schematic diagram illustrating an example of a deformable electrical device 1600, in accordance with some embodiments of the present disclosure. The substrate 1601 includes a plurality of channels 1610 with filling ports formed on both ends of each channel. Alloyed LM (ALM, e.g., EGain) 1620 covers the filling ports on one side of the channels, and the other side is connected to a vacuum chamber 1630. FIG. 17 below shows the channels filled with the LM by suction, forming a plurality of deformable LM traces and a plurality of vias (e.g., vias adjacent to both ends of the channels).

FIG. 17 is a schematic diagram illustrating an example of a deformable electrical device 1700, in accordance with some embodiments of the present disclosure. FIG. 17 illustrates a substrate 1701 including a plurality of channels with filling ports formed on both ends of each channel. The filling ports on one side of the channels is covered by an LM, and then capped with a compartment 1710, which can be used to assist the injection. In some embodiments, the compartment 1710 is an acrylic compartment and nitrogen gas can be turned on to assist the injection. The other side is connected to a vacuum chamber 1730 to suck the LM to the plurality of channels. Advantageously, the combination of suction and injection has been reported that dramatically reduces the patterning time (e.g., to 2-3 hours). The combination of suction and injection (or suction/pressure) method of the present disclosure makes the deformable LM traces in less than 2 seconds, reducing the patterning time by 4 orders of magnitude.

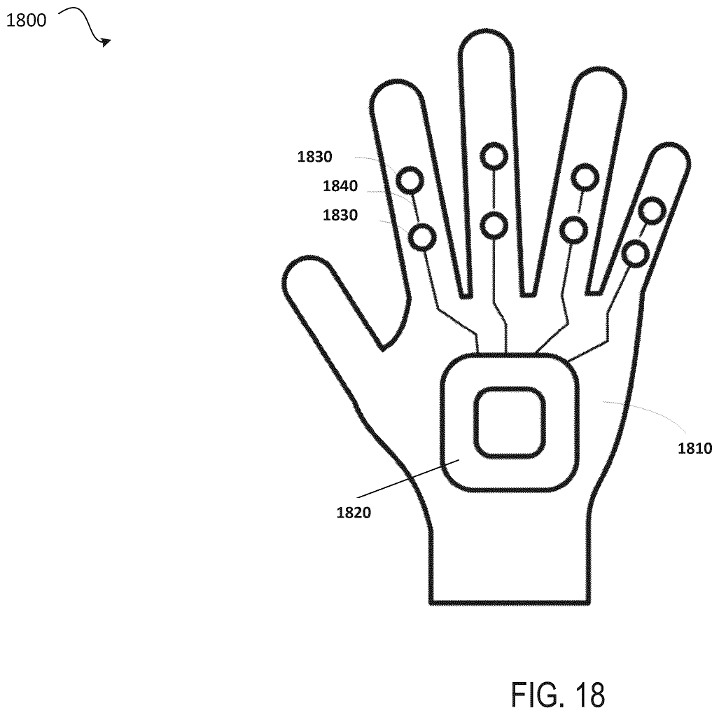

FIG. 18 is a schematic diagram illustrating an example of an implementation of the deformable electronic device in the form of a glove, in accordance with some embodiments of the present disclosure. As disclosed herein, the deformable parts and deformable interconnects of the present disclosure allow for configuring highly complex electronic devices that can function properly even when the devices are physically deformed. Accordingly, the electronic device 300 of FIG. 3 can be implemented in various forms, shapes and/or sizes and can be used in a number of fields, such as medical robots, augmented reality (AR), and virtual reality (VR). For instance, the electronic device 300 can be implemented as a wearable device worn by a subject (e.g., a human or a robot) or attached to a subject. Examples of such a wearable device include but are not limited to a garment worn by a subject around a wrist (wristband), a hand (glove), a finger, or a combination thereof of the subject.

As a non-limiting example, FIG. 18 illustrates an exemplary implementation of the electronic device 1800 in the form of a glove, generally designated glove 1810, in accordance with some embodiments of the present invention. In some embodiments, glove 1810 is formed of a deformable base material and includes one or more ICs (e.g., the circuit component 310 of FIG. 3) electrically connected to deformable electronic parts 1830 (e.g., the electronic part 330 of FIG. 3) by deformable interconnects 1840 (e.g., the deformable interconnects 340, 350 of FIG. 3). While FIG. 18 illustrates that a single circuit component 1820 is disposed at the palm, it should be noted that this is by way of illustration, and it is non-limiting. The glove 1810 can include any suitable number of ICs, which can be disposed anywhere in the glove, such as a finger, the palm or a place other than a finger/palm.

In some embodiments, glove 1810 has a number of ICs, for example, a number within a range of 2 to 100 ICs. In some embodiments, an IC includes one or more terminals, one or more resistors, one or more transistors, one or more capacitors, one or more inductors, one or more transformers, one or more diodes, one or more sensors, or any combination thereof.

In some embodiments, the glove 1810 includes one or more other components formed or attached to the electronic parts 1830. For instance, as a non-limiting example, glove 1810 includes a plurality of circuit components, for example, a terminal, an energy source (e.g., power supply), an interconnect (e.g., a line interconnect, such as a wire), a load (e.g., a device, a sensor, etc.), a controller (e.g., switch), a resistor, a transistor, a capacitor, an inductor, a transformer, a diode, a contact pad or a combination thereof.

In some embodiments, the electronic parts 1830 form the base of the glove. In some embodiments, the base of the glove is formed of a material, to which the electronic device is attached or with which the electronic device is integrated. Examples of the material for the base include but are not limited to fabric, leather, textiles, fibers, vinyl, silicone, and plastic. The base made of such a material can conform to the shape of a user's hand and allow the substrates of the electronic device to deform (e.g., expend, contract, bend, twist).

An aspect of the subject technology is directed to a method including obtaining a first integrated circuit (IC) comprising a first plurality of contacts and/or pins, obtaining an electronic part comprising a first plurality of circuit components corresponding to the first plurality of contacts and/or pins and forming a first layer over the first plurality of circuit components. The method further includes forming a first plurality of LM interconnects in the first layer at locations corresponding to the first plurality of circuit components.

In some implementations, forming the first plurality of LM interconnects comprises forming each respective LM interconnect in the first plurality of LM interconnects to expose at least a portion of a corresponding circuit component in the first plurality of circuit components.

In one or more implementations, forming the first plurality of LM interconnects comprises forming a plurality of first holes by drilling, using a laser beam, the first layer at locations corresponding to the first plurality of circuit components of the electronic part.

In some implementations, the method further comprises placing the first plurality of contacts and/or pins of the first IC into the first plurality of holes filled with the first LM material, thereby producing a first plurality of deformable interconnects.

In one or more implementations, the method further comprises, prior to the filling the first plurality of holes, applying a first metal material to form a wetting layer that overlays at least a portion of a wall of each hole in the first plurality of holes.

In some implementations, the first plurality of deformable interconnects electrically connect the first plurality of contacts and/or pins of the first IC with the first plurality of circuit components of the electronic part.

In one or more implementations, the method further comprises underfilling a gap between the first IC and the electronic part with a material to provide a bond between the first IC and the electronic part.

In some implementations, the method further comprises degassing the first plurality of holes prior to filling the first plurality of holes.

In one or more implementations, the method further comprises obtaining a second IC including a second plurality of contacts and/or pins, wherein the electronic part includes a second plurality of circuit components corresponding to the second plurality of contacts and/or pins of the second IC and covered by a second layer of the electronic part.

In some implementations, the method further comprises forming a second plurality of holes in the first layer of the electronic part at locations corresponding to the second plurality of circuit components, wherein each respective hole in the second plurality of holes exposing at least a portion of a corresponding circuit component in the second plurality of circuit components.

In one or more implementations, the method further comprises filling the second plurality of holes with a second LM material and placing the second plurality of contacts and/or pins of the second IC into the second plurality of holes filled with the second LM material, thereby producing a second plurality of deformable interconnects that electrically connects the second plurality of contacts and/or pins of the second IC with the second plurality of circuit components of the electronic part.

Another aspect of the subject technology is directed to a method including obtaining a substrate comprising a first dielectric layer, a second dielectric layer, at least one middle dielectric layer sandwiched between the first dielectric layer and the second dielectric layer, a first plurality of channels, each disposed in the first dielectric layer and a second plurality of channels, each disposed in the second dielectric layer. The method further includes forming a plurality of ports and filling the first plurality of channels and the second plurality of channels, through at least a subset of the plurality of ports, with an LM, thereby producing a plurality of deformable LM components.

In some implementations, each respective port in the plurality of ports provides fluid communication for (i) a corresponding channel in the first plurality of channels through the at least one middle dielectric layer, and/or (ii) a corresponding channel in the second plurality of channels through the at least one middle dielectric layer.

In one or more implementations, the plurality of deformable LM components include a first plurality of deformable LM traces produced by filling the first plurality of channels, a second plurality of deformable LM traces produced by filling the second plurality of channels and a plurality of deformable LM vias produced by filling at least the subset of the plurality of ports.

In some implementations, the method further comprises, prior to filling the first plurality of channels and the second plurality of channels, using a first cap layer to cover the first layer and a second cap layer to cover a second layer formed over a second plurality of circuit components.

In one or more implementations, the method further comprises degassing the first plurality of channels and the second plurality of channels prior to filling the first plurality of channels and the second plurality of channels.

In some implementations, the method further comprises placing the LM on top of a first set of the plurality of ports, allowing the LM to fill the first plurality of channels and the second plurality of channels, and applying positive pressure to the LM on top of the first set of the plurality of ports, thereby pushing the LM into the first plurality of channels and the second plurality of channels.

Yet another aspect of the subject technology is directed to an electronic device including a first IC comprising a first plurality of contacts and/or pins and a second IC comprising a second plurality of contacts and/or pins, an electronic part comprising a first plurality of circuit components corresponding to the first plurality of contacts and/or pins and a second plurality of circuit components corresponding to the second plurality of contacts and/or pins of the second IC. The electronic device further includes a first layer over the first plurality of circuit components and a second layer over the second plurality of circuit components.

In one or more implementations, the electronic device further includes a first IC comprising a first plurality of contacts and/or pins and a second IC comprising a second plurality of contacts and/or pins, an electronic part comprising a first plurality of circuit components corresponding to the first plurality of contacts and/or pins and a second plurality of circuit components corresponding to the second plurality of contacts and/or pins of the second IC, and a first layer over the first plurality of circuit components and a second layer over the second plurality of circuit components.

In some implementations, the first plurality of contacts and/or pins of the first IC are placed into a first plurality of holes filled with the LM material, thereby producing a first plurality of deformable interconnects, and the second plurality of contacts and/or pins of the second IC are placed into a second plurality of holes filled with the LM material, thereby producing a second plurality of deformable interconnects.

In some implementations, the word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” Pronouns in the masculine (e.g., his) include the feminine and neuter gender (e.g., her and its) and vice versa. The term “some” refers to one or more. Underlined and/or italicized headings and subheadings are used for convenience only, do not limit the subject technology, and are not referred to in connection with the interpretation of the description of the subject technology. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public, regardless of whether such disclosure is explicitly recited in the above description. No clause element is to be construed under the provisions of 35 U.S.C. § 112, sixth paragraph, unless the element is expressly recited using the phrase “means for” or, in the case of a method clause, the element is recited using the phrase “step for.”

While this specification contains many specifics, these should not be construed as limitations on the scope of what may be described, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially described as such, one or more features from a described combination can in some cases be excised from the combination, and the described combination may be directed to a sub-combination or variation of a sub-combination.

The subject matter of this specification has been described in terms of particular aspects, but other aspects can be implemented and are within the scope of the following clauses. For example, while operations are depicted in the drawings in a particular order, this should not be understood as requiring that such operations be performed in the particular order shown or in sequential order, or that all illustrated operations be performed, to achieve desirable results. The actions recited in the clauses can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the clauses. In addition, in the detailed description, it can be seen that the description provides illustrative examples, and the various features are grouped together in various implementations for the purpose of streamlining the disclosure. The method of disclosure is not to be interpreted as reflecting an intention that the described subject matter requires more features than are expressly recited in each clause. Rather, as the clauses reflect, inventive subject matter lies in less than all features of a single disclosed configuration or operation. The clauses are hereby incorporated into the detailed description, with each clause standing on its own as a separately described subject matter.

As used herein, the phrase “at least one of” preceding a series of items, with the terms “and” or “or” to separate any of the items, modifies the list as a whole, rather than each member of the list (i.e., each item).

To the extent that the term “include,” “have,” or the like is used in the description or the claims, such term is intended to be inclusive in a manner similar to the term “comprise” as “comprise” is interpreted when employed as a transitional word in a claim.

A reference to an element in the singular is not intended to mean “one and only one” unless specifically stated, but rather “one or more.” All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. A method, comprising:
obtaining a first electronic component comprising a first plurality of contacts and/or pins;
obtaining an electronic part comprising a first plurality of circuit components corresponding to the first plurality of contacts and/or pins;
forming a first layer over the first plurality of circuit components; and
forming a first plurality of liquid metal (LM) interconnects in the first layer at locations corresponding to the first plurality of circuit components.

2. The method of claim 1, wherein forming the first plurality of LM interconnects comprises forming each respective LM interconnect in the first plurality of LM interconnects to expose at least a portion of a corresponding circuit component in the first plurality of circuit components.

3. The method of claim 1, wherein the first layer at locations corresponding to the first plurality of circuit components of the electronic part.

4. The method of claim 3, further comprising placing the first plurality of contacts and/or pins of the first electronic component into the first plurality of LM interconnects formed with a first LM material, thereby producing a first plurality of deformable interconnects.

5. The method of claim 4, wherein the first plurality of deformable interconnects electrically connect the first plurality of contacts and/or pins of the first electronic component with the first plurality of circuit components of the electronic part.

6. The method of claim 4, further comprising, applying a first metal material to form a wetting layer that overlays at least a portion of a wall of each LM interconnect in the first plurality of LM interconnects.

7. The method of claim 6, further comprising underfilling a gap between the first electronic component and the electronic part with a material to provide a bond between the first electronic component and the electronic part.

8. The method of claim 6, further comprising degassing the first plurality of LM interconnects.

9. The method of claim 1, further comprising obtaining a second electronic component including a second plurality of contacts and/or pins, wherein the electronic part includes a second plurality of circuit components corresponding to the second plurality of contacts and/or pins of the second electronic component and covered by a second layer of the electronic part.

10. The method of claim 9, further comprising forming a second plurality of LM interconnects in the first layer of the electronic part at locations corresponding to the second plurality of circuit components, wherein each respective LM interconnect in the second plurality of LM interconnects exposes at least a portion of a corresponding circuit component in the second plurality of circuit components.

11. The method of claim 10, further comprising:
forming the second plurality of LM interconnects with a second LM material; and
placing the second plurality of contacts and/or pins of the second electronic component into the second plurality of LM interconnects formed with the second LM material, thereby producing a second plurality of deformable interconnects that electrically connects the second plurality of contacts and/or pins of the second electronic component with the second plurality of circuit components of the electronic part.

12. A method, comprising:
obtaining a substrate comprising, a first plurality of channels and a second plurality of channels;
forming a plurality of ports; and
filling the first plurality of channels and the second plurality of channels, through at least a subset of the plurality of ports, with an LM, thereby producing a plurality of deformable LM components.

13. The method of claim 12, wherein each respective port in the plurality of ports provides fluid communication for (i) a corresponding channel in the first plurality of channels, and/or (ii) a corresponding channel in the second plurality of channels.

14. The method of claim 12, wherein the plurality of deformable LM components include a first plurality of deformable LM traces produced by filling the first plurality of channels, a second plurality of deformable LM traces produced by filling the second plurality of channels and a plurality of deformable LM vias produced by filling at least the subset of the plurality of ports.

15. The method of claim 14, wherein each respective deformable via in the plurality of deformable LM vias is in electrical communication with at least one of a corresponding deformable LM trace in the first plurality of LM traces and a corresponding deformable LM trace in the second plurality of LM traces.

16. The method of claim 15, further comprising degassing the first plurality of channels and the second plurality of channels prior to filling the first plurality of channels and the second plurality of channels.

17. The method of claim 12, further comprising:
placing the LM on top of a first set of the plurality of ports;
allowing the LM to fill the first plurality of channels and the second plurality of channels; and
applying positive pressure to the LM on top of the first set of the plurality of ports, thereby pushing the LM into the first plurality of channels and the second plurality of channels.

18. An electronic device, comprising:
a first plurality of channels and a second plurality of channels;
a plurality of ports; and
a plurality of deformable LM components formed by filling the first plurality of channels and the second plurality of channels, through at least a subset of the plurality of ports, with an LM material.

19. The electronic device of claim 18, further comprising:
a first electronic component comprising a first plurality of contacts and/or pins and a second electronic component comprising a second plurality of contacts and/or pins;
an electronic part comprising a first plurality of circuit components corresponding to the first plurality of contacts and/or pins and a second plurality of circuit components corresponding to the second plurality of contacts and/or pins of the second electronic component; and
a first layer over the first plurality of circuit components and a second layer over the second plurality of circuit components.

20. The electronic device of claim 19, wherein:
the first plurality of contacts and/or pins of the first electronic component are placed into a first plurality of LM interconnects formed with the LM material, thereby producing a first plurality of deformable interconnects; and
the second plurality of contacts and/or pins of the second electronic component are placed into a second plurality of LM interconnects filled with the LM material, thereby producing a second plurality of deformable interconnects.
